(19) United States
(12) Patent Application Publication
(10) Pub. No.: US 2024/0122022 A1
(43) Pub. Date: Apr. 11, 2024

(54) DISPLAY DEVICE

(71) Applicant: SONY SEMICONDUCTOR SOLUTIONS CORPORATION, KANAGAWA (JP)

(72) Inventors: KEIICHI YAGI, KANAGAWA (JP); KIWAMU MIURA, KANAGAWA (JP); CHUGEN HAMACHI, KANAGAWA (JP)

(21) Appl. No.: 18/251,546

(22) PCT Filed: Oct. 29, 2021
(86) PCT No.: PCT/JP2021/039965

§ 371 Date: May 3, 2023

(30) Foreign Application Priority Data
Nov. 11, 2020 (JP) 2020-187970

(51) Int. Cl. H10K 59/38; H10K 59/126; H10K 59/127; H10K 59/80

(52) U.S. Cl. CPC H10K 59/38; H10K 59/126; H10K 59/127; H10K 59/8722

(57) ABSTRACT

A display device includes a first substrate (41), a second substrate (42), a plurality of light emitting elements (10) provided in a display region, and a sealing part (50) that is provided in a peripheral region surrounding the display region and seals between the first substrate (41) and the second substrate (42), wherein the sealing part (50) includes main sealing parts (51) and a sub sealing part (52) positioned between the main sealing parts, an alignment mark (55) is provided between the sub sealing part (52) and the first substrate (41), each of the main sealing part (51) has a stacked structure of a light shielding member layer (56, 57) and a sealing member layer (53) from the first substrate side, and the sub sealing part (52) has a stacked structure (53) of a base material layer (54) formed of a non-light shielding member and the sealing member layer from the first substrate side.

### FIELD

The present disclosure relates to a display device.

### BACKGROUND

Display devices in which organic electroluminescence (EL) elements are used as light emitting elements (organic EL display devices) have recently been developed. In a light emitting element constituting an organic EL display device, an organic layer including at least a light emitting layer and a second electrode (upper electrode, e.g. cathode electrode) are formed on a first electrode (lower electrode, e.g. anode electrode) formed separately for each pixel, for example. For example, a red light emitting element in which an organic layer that emits white light or red light and a red color filter layer are combined, a green light emitting element in which an organic layer that emits white light or green light and a green color filter layer are combined, and a blue light emitting element in which an organic layer that emits white light or blue light and a blue color filter layer are combined, are each provided as a subpixel, and these subpixels constitute one pixel (light emitting element unit). Light from the organic layers is emitted outside via the second electrode (upper electrode). In addition, a peripheral region (outer peripheral part) of the first substrate provided with light emitting elements and a drive circuit for driving the light emitting elements and the second substrate facing the first substrate are sealed by a sealing member, which prevents the light emitting elements from deteriorating because of entering of moisture and improves reliability of the display device.

There is a known light emitting device from JP 2015-076298 A having a structure in which a sealing layer 71 and a protective layer 96 are stacked. The protective layer 96 has a stacked structure of a red color filter layer, a green color filter layer, and a blue color filter layer, and it has a light shielding property. The stacked structure of the sealing layer 71 and the protective layer 96 surrounds a display region in a frame shape.

### CITATION LIST

### Patent Literature

Patent Literature 1: JP 2015-076298 A

### SUMMARY

### Technical Problem

In the manufacture of display devices, various components of light emitting elements and the like need to be formed on or above a first substrate. Then, alignment of each component and the like is important, and for this purpose, it is necessary to provide an alignment mark for alignment in a peripheral region on the first substrate side, for example. With the peripheral region having a large width, the alignment mark may be provided at an appropriate position, but with the peripheral region having a small width, the alignment mark needs to be provided at a position overlapping a sealing member. When the technique disclosed in the above-mentioned patent publication is applied, the alignment mark is hidden by the protective layer 96 having a light shielding property, and the alignment mark cannot be detected.

An object of the present disclosure is to provide a display device having a configuration and a structure with which the alignment mark can be reliably detected at the time of manufacturing.

### Solution to Problem

A display device of the present disclosure in order to solve the above object includes:
a first substrate;
a second substrate facing the first substrate;
a plurality of light emitting elements provided in a display region sandwiched between the first substrate and the second substrate; and
a sealing part that is provided in a peripheral region sandwiched between the first substrate and the second substrate and surrounding the display region, the sealing part sealing between the first substrate and the second substrate, wherein
the sealing part includes main sealing parts and a sub sealing part positioned between the main sealing parts,
an alignment mark is provided between the sub sealing part and the first substrate,
each of the main sealing part has a stacked structure of a light shielding member layer and a sealing member layer from the first substrate side, and
the sub sealing part has a stacked structure of a base material layer formed of a non-light shielding member and the sealing member layer from the first substrate side.

### BRIEF DESCRIPTION OF DRAWINGS

FIG. 1 is a schematic and partial sectional view of a display device of Example 1 taken along the arrow A-A in FIG. 3.

FIG. 2 is a schematic and partial sectional view of the display device of Example 1 taken along the arrow B-B in FIG. 3.

FIG. 3 is a diagram schematically illustrating an arrangement state of a display region, a peripheral region, a first substrate, and a sealing part constituting the display device of Example 1.

FIG. 4A is a diagram schematically illustrating an array of light emitting elements in a light emitting element unit constituting the display device of Example 1.

FIG. 4B is a diagram schematically illustrating an array of light emitting elements in the light emitting element unit constituting the display device of Example 1.

FIG. 4C is a diagram schematically illustrating an array of light emitting elements in the light emitting element unit constituting the display device of Example 1.

FIG. 4D is a diagram schematically illustrating an array of light emitting elements in the light emitting element unit constituting the display device of Example 1.

FIG. 4E is a diagram schematically illustrating an array of light emitting elements in the light emitting element unit constituting the display device of Example 1.

FIG. 5 is a schematic and partial sectional view of a modification of the display device of Example 1 taken along the arrow A-A in FIG. 3.

FIG. 6 is a schematic and partial sectional view of Modification-2 of the display device of Example 1 taken along the arrow A-A in FIG. 3.

FIG. 7 is a schematic and partial sectional view of Modification-3 of the display device of Example 1 taken along the arrow A-A in FIG. 3.

FIG. 8 is a schematic and partial sectional view of Modification-4 of the display device of Example 1 taken along the arrow A-A in FIG. 3.

FIG. 9 is a schematic and partial sectional view of a light emitting element constituting Modification-5 of the display device of Example 1.

FIG. 10 is a schematic and partial sectional view of a light emitting element for explaining behavior of light from the light emitting element constituting Modification-5 of the display device of Example 1.

FIG. 11 is a schematic and partial sectional view of a light emitting element constituting Modification-6 of the display device of Example 1.

FIG. 12A is a schematic and partial end view of a base and the like for explaining a method for producing the light emitting element constituting Modification-5 of the display device of Example 1.

FIG. 12B is a schematic and partial end view of the base and the like for explaining the method for producing the light emitting element constituting Modification-5 of the display device of Example 1.

FIG. 12C is a schematic and partial end view of the base and the like for explaining the method for producing the light emitting element constituting Modification-5 of the display device of Example 1.

FIG. 13A is a schematic and partial end view of the base and the like for explaining the method for producing the light emitting element constituting Modification-5 of the display device of Example 1 following FIG. 12C.

FIG. 13B is a schematic and partial end view of the base and the like for explaining the method for producing the light emitting element constituting Modification-5 of the display device of Example 1 following FIG. 12C.

FIG. 14A is a schematic and partial end view of a base and the like for explaining another method for producing the light emitting element constituting Modification-5 of the display device of Example 1.

FIG. 14B is a schematic and partial end view of a base and the like for explaining the other method for producing the light emitting element constituting Modification-5 of the display device of Example 1.

FIG. 15 is a schematic and partial sectional view of a display device of Example 2 similar to a view taken along the arrow A-A in FIG. 3.

FIG. 16 is a schematic and partial sectional view of a modification of the display device of Example 2 similar to a view taken along the arrow A-A in FIG. 3.

FIG. 17 is a schematic and partial sectional view of a display device of Example 3 similar to a view taken along the arrow A-A in FIG. 3.

FIG. 18 is a schematic and partial sectional view of the display device of Example 3 similar to a view taken along the arrow B-B in FIG. 3.

FIG. 19 is a schematic and partial sectional view of a display device of Example 4 similar to a view taken along the arrow A-A in FIG. 3.

FIG. 20 is a schematic and partial sectional view of the display device of Example 4 similar to a view taken along the arrow B-B in FIG. 3.

FIG. 21 is a schematic and partial sectional view of the display device of Example 4 similar to a view taken along the arrow A-A in FIG. 3.

FIG. 22 is a schematic and partial sectional view of the display device of Example 4 similar to a view taken along the arrow B-B in FIG. 3.

FIG. 23 is a schematic and partial sectional view of Modification-1 of the display device of Example 4 similar to a view taken along the arrow A-A in FIG. 3.

FIG. 24 is a schematic and partial sectional view of Modification-1 of the display device of Example 4 similar to a view taken along the arrow B-B in FIG. 3.

FIG. 25 is a schematic and partial sectional view of Modification-2 of the display device of Example 4 similar to a view taken along the arrow A-A in FIG. 3.

FIG. 26 is a schematic and partial sectional view of Modification-2 of the display device of Example 4 similar to a view taken along the arrow B-B in FIG. 3.

FIG. 27 is a schematic and partial sectional view of Modification-2 of the display device of Example 4 similar to a view taken along the arrow A-A in FIG. 3.

FIG. 28 is a schematic and partial sectional view of Modification-2 of the display device of Example 4 similar to a view taken along the arrow B-B in FIG. 3.

FIG. 29A includes a schematic plan view and a schematic perspective view of a lens member having a truncated quadrangular pyramid shape.

FIG. 29B includes a schematic plan view and a schematic perspective view of the lens member having a truncated quadrangular pyramid shape.

FIG. 30 is a schematic and partial sectional view of a display device provided with a light emission direction control member.

FIG. 31A is a front view of a digital still camera illustrating an example in which a display device of the present disclosure is applied to a mirrorless interchangeable lens digital still camera.

FIG. 31B is a back view of the digital still camera illustrating the example in which the display device of the present disclosure is applied to a mirrorless interchangeable lens digital still camera.

FIG. 32 is an external view of a head mounted display illustrating an example in which the display device of the present disclosure is applied to a head mounted display.

FIG. 33 is a schematic and partial sectional view of a display device having a resonator structure.

FIG. 34A is a conceptual diagram of light emitting elements having a first example of the resonator structure in a display device of Examples.

FIG. 34B is a conceptual diagram of light emitting elements having a second example of the resonator structure in the display device of Examples.

FIG. 35A is a conceptual diagram of light emitting elements having a third example of the resonator structure in the display device of Examples.

FIG. 35B is a conceptual diagram of light emitting elements having a fourth example of the resonator structure in the display device of Examples.

FIG. 36A is a conceptual diagram of light emitting elements having a fifth example of the resonator structure in the display device of Examples.

FIG. 36B is a conceptual diagram of light emitting elements having a sixth example of the resonator structure in the display device of Examples.

FIG. 37A is a conceptual diagram of light emitting elements having a seventh example of the resonator structure.

FIG. 37B is a conceptual diagram of light emitting elements having an eighth example of the resonator structure.

FIG. 37C is a conceptual diagram of light emitting elements having the eighth example of the resonator structure.

FIG. 38 is a schematic and partial sectional view of a reference example of a display device similar to a view taken along the arrow A-A in FIG. 3 except that a base material layer formed of a non-light shielding member is not provided in a sub sealing part.

### DESCRIPTION OF EMBODIMENTS

Hereinafter, the present disclosure will be described based on Examples with reference to the drawings. The present disclosure is not limited to Examples, and various numerical values and materials in Examples are examples. The description will be given in the following order.
1. Overall description of display device of present disclosure
2. Example 1 (display device of the present disclosure)
3. Example 2 (modification of Example 1)
4. Example 3 (modification of Examples 1 and 2)
5. Example 4 (modification of Examples 1 to 3)
6. Others

### Overall Description of Display Device of Present Disclosure

In a display device of the present disclosure, an extending part of the sealing member layer constituting the sub sealing part may be formed on a light shielding member layer.

In the display device of the present disclosure including the above preferable embodiment,
each of the light emitting elements may include a first electrode, an organic layer, a second electrode, and an optical path control unit from the first substrate side, and
the base material layer may be made of a material constituting the optical path control unit.

In such a configuration,
the light emitting element may include a color filter layer between the second electrode and the optical path control unit, and
the light shielding member layer may be made of a material constituting the color filter layer, and further,
the light emitting element may include a planarization layer between the second electrode and the color filter layer, and
the base material layer may be made of a material constituting the planarization layer.

In the following description, the first electrode, the organic layer, and the second electrode constituting the light emitting element may be collectively referred to as “light emitting unit”.

In the display device of the present disclosure including the preferable forms and configurations described above (hereinafter, these may be collectively referred to as a “display device or the like of the present disclosure”), the plurality of light emitting elements may be classified into a plurality of types of light emitting elements, and the display device or the like of the present disclosure may include a plurality of light emitting element units composed of the plurality of types of light emitting elements. Specifically, one light emitting element unit (pixel) may be composed of three types of three light emitting elements (sub pixels). In such a case, a first light emitting element may emit red light, a second light emitting element may emit green light, and a third light emitting element may emit blue light. Further, a fourth light emitting element that emits white light or a fourth light emitting element that emits light of a color other than red light, green light, or blue light may be added. In the display device or the like of the present disclosure, light from the organic layer is emitted outside via the second substrate. That is, the display device or the like of the present disclosure may be a top emission type display device that emits light from the second substrate.

Then, the color filter layer may be provided above the light emitting unit, and the optical path control unit may be provided on or above the color filter layer, or the optical path control unit may be provided beneath or below the color filter layer. In the present specification, “upper” and “lower” are with respect to the first substrate. The color filter layer may be provided on the first substrate side or may be provided on the second substrate side.

Examples of the color filter layer include a color filter layer that transmits not only red, green, and blue, but also specific wavelengths such as cyan, magenta, and yellow in some cases. The color filter layer is made of a resin (for example, a photocurable resin) to which a colorant including a desired pigment or dye is added. By selecting a pigment or dye, the light transmittance of the color filter layer is adjusted to be high in a target wavelength region such as red, green, and blue and low in other wavelength regions. Specifically, such a color filter layer may be made of a known color resist material. When the light emitting element unit (pixel) further includes a light emitting element that emits white light, a transparent filter layer may be disposed in the light emitting element. The size of the color filter layer or a wavelength selection unit (hereinafter, these may be collectively referred to as “color filter layer or the like”) to be described later may be appropriately changed according to the light emitted from the light emitting element.

External light toward the peripheral region and light reflected by the peripheral region are shielded by the light shielding member layer. Thus, reflected light at the peripheral wiring is less likely to be perceived by the observer, and reflection of an external object or the like is less likely to be perceived by the observer. Examples of the material constituting the light shielding member layer include materials constituting the color filter layer as described above, and specific examples thereof include a stacked structure of a red color filter layer and a blue color filter layer, a stacked structure of a red color filter layer and a green color filter layer, a stacked structure of a green color filter layer and a blue color filter layer, and a stacked structure of a red color filter layer, a green color filter layer, and a blue color filter layer. A display device in which the light shielding member layer is made of a material constituting the color filter layer like this is referred to as “display device of configuration 1-A” for convenience. Examples of the material constituting the light shielding member layer also include a thermosetting resin colored in black or the like (for example, an acrylic resin, an epoxy resin, a urethane resin, a silicone resin, or a cyanoacrylate resin), an ultraviolet curable resin, and a light photosensitive resin. A display device in which the light shielding member layer is made of a material other than the material constituting the color filter layer is referred to as “display device of configuration 1-B” for convenience. When the color filter layer is provided on the first substrate side, the display device of configuration 1-A or the display device of configuration 1-B may be adopted, and when the color filter layer is provided on the second substrate side, the display device of configuration 1-B may be adopted.

Examples of the material constituting the sealing member layer include thermosetting resins (for example, an acrylic resin, an epoxy resin, a urethane resin, a silicone resin, or a cyanoacrylate resin), ultraviolet curable resins, and photosensitive resins. A spherical spacer may be mixed in the material constituting the sealing member layer to control the thickness of the sealing part, for example.

Further, the base material layer formed of the non-light shielding member is not only made of the material constituting the optical path control unit (a display device having such a configuration is referred to as “display device of configuration 2-A” for convenience), but it may also have a stacked structure of a first layer made of the material constituting the planarization layer and a second layer formed of the material constituting the optical path control unit from the first substrate side (a display device having such a configuration is referred to as “display device of configuration 2-B” for convenience). However, the display device of the present disclosure is not limited to these configurations, and in some cases, the base material layer may be made only of the material forming the planarization layer (a display device having such a configuration is referred to as “display device of configuration 2-C” for convenience), or the base material layer may be made of a material other than the material forming the planarization layer and the material forming the optical path control unit, that is, in a broad sense, a material transparent to light (hereinafter, it may be referred to as “transparent material”) for detecting an alignment mark (a display device having such a configuration is referred to as “display device of configuration 2-D” for convenience).

The optical path control unit may be formed of a plano-convex lens having a convex shape in a direction away from the second electrode. That is, the light emission surface of the optical path control unit may have a convex shape, and the light incident surface may be flat, for example. In this case, the optical path control unit is provided on the first substrate side. Then, the display device of configuration 2-A, the display device of configuration 2-B, the display device of configuration 2-C, or the display device of configuration 2-D may be formed.

The optical path control unit may also be formed of a plano-convex lens having a convex shape toward the second electrode. That is, the light incident surface of the optical path control unit may have a convex shape, and the light emission surface may be flat, for example. In this case, the optical path control unit is provided on the second substrate side. Then, the display device of configuration 2-C or the display device of configuration 2-D described above may be formed.

The optical path control unit may be made of, for example, a known transparent resin material such as an acrylic resin, and it may be obtained by melt-flowing the transparent resin material, may be obtained by etching back the transparent material, may be obtained by a combination of a photolithography technique using a gray tone mask or a halftone mask and an etching method based on an organic material or an inorganic material, or may be obtained by a method of forming the transparent resin material based on a nanoimprint method. Examples of the outer shape of the optical path control unit include, but are not limited to, a circle, an ellipse, a square, and a rectangle.

In the display device or the like of the present disclosure, the sealing part includes a main sealing part and a sub sealing part positioned between the main sealing part and the main sealing part, and the number of the sub sealing parts may be two or more. When the number of the sub sealing parts is two, a first main sealing part, a first sub sealing part, a second main sealing part, a second sub sealing part, and a first main sealing part are connected to form the sealing part. When the number of the sub sealing parts is four, a first main sealing part, a first sub sealing part, a second main sealing part, a second sub sealing part, a third main sealing part, a third sub sealing part, a fourth main sealing part, a fourth sub sealing part, and a first main sealing part are connected to form the sealing part. There is no gap between the main sealing part and the sub sealing part.

An alignment mark is provided between the sub sealing part and the first substrate. Specifically, the alignment mark may be formed of a metal layer, an alloy layer, or the like provided on or above the first substrate. The alignment mark is covered with, for example, an insulating material, and the sub sealing part is provided on or above the insulating material. The alignment mark is provided in the peripheral region, but it may be provided essentially anywhere in the peripheral region. The alignment mark is used for photomask positioning in various lithography processes. It is also used as a line width measurement mark and a misalignment measurement mark.

In the display device or the like of the present disclosure including the various preferable forms and configurations described above, the light emitting unit (organic layer) may include an organic electroluminescence layer. That is, the display device or the like of the present disclosure including the various preferable forms and configurations described above may be provided with an organic electroluminescence element (organic EL element), or the display device of the present disclosure may be formed of an organic electroluminescence display device (organic EL display device).

Examples of the array of the pixels (or subpixels) in the display device of the present disclosure include delta array, stripe array, diagonal array, rectangle array, Pentile array, and square array. The array of the color filter layer or the like may be a delta array, a stripe array, a diagonal array, a rectangle array, a Pentile array, or a square array in accordance with the array of the pixels (or subpixels).

Specifically, the display device or the like of the present disclosure includes a first electrode, an organic layer formed on the first electrode, a second electrode formed on the organic layer, and a protective layer formed on the second electrode. The optical path control unit is formed on the protective layer or above the protective layer. Then, light from the organic layer is emitted outside via the second electrode, the protective layer, the optical path control unit, and the second substrate, or via the second electrode, the protective layer, the planarization layer, the optical path control unit, and the second substrate in some cases, and also via the color filter layer or the like and an underlayer when the color filter layer or the like is provided in these optical paths of the emitted light or when the underlayer is provided on the inner surface (surface facing the first substrate) of the second substrate.

The first electrode is provided for each light emitting element. The organic layer including a light emitting layer made of an organic light emitting material is provided for each light emitting element or is shared by light emitting elements. That is, in the latter case, the organic layer is a so-called solid film. The second electrode is shared by a plurality of light emitting elements. That is, the second electrode is a so-called solid electrode and is also a common electrode. The light emitting unit is formed on the first substrate side, and the light emitting unit is provided on a base. Specifically, the light emitting unit is provided on the base formed on or above the first substrate. The second substrate is disposed above the second electrode. In this manner, the first electrode, the organic layer (including the light emitting layer), and the second electrode constituting the light emitting unit are sequentially formed on the base.

In the display device or the like of the present disclosure, the first electrode may be in contact with a part of the organic layer, a part of the first electrode may be in contact with the organic layer, or the first electrode may be in contact with the organic layer. In these cases, specifically, the size of the first electrode may be smaller than the size of the organic layer, the size of the first electrode may be the same as the size of the organic layer, or the size of the first electrode may be larger than the size of the organic layer. An insulating layer may be formed in a part between the first electrode and the organic layer. A region where the first electrode and the organic layer are in contact with each other is a light emitting region. The size of the light emitting region is the size of the region where the first electrode and the organic layer are in contact with each other. The size of the light emitting region may be changed according to the color of light to be emitted from the light emitting element.

In the display device or the like of the present disclosure, the organic layer may have a stacked structure of at least two light emitting layers that emit different colors, and the color of light emitted in the stacked structure may be white light. That is, an organic layer constituting a red light emitting element (first light emitting element), an organic layer constituting a green light emitting element (second light emitting element), and an organic layer constituting a blue light emitting element (third light emitting element) may be configured to emit white light. In this case, the organic layer that emits white light may have a stacked structure of a red light emitting layer that emits red light, a green light emitting layer that emits green light, and a blue light emitting layer that emits blue light. Alternatively, the organic layer that emits white light may have a stacked structure of a blue light emitting layer that emits blue light and a yellow light emitting layer that emits yellow light, or may have a stacked structure of a blue light emitting layer that emits blue light and an orange light emitting layer that emits orange light. Specifically, the organic layer may have a stacked structure in which three layers of a red light emitting layer that emits red light (wavelength: 620 nm to 750 nm), a green light emitting layer that emits green light (wavelength: 495 nm to 570 nm), and a blue light emitting layer that emits blue light (wavelength: 450 nm to 495 nm) are stacked, and the organic layer emits white light as a whole. Such an organic layer (light emitting unit) that emits white light and a color filter layer or the like that passes red light (or a protective layer that functions as a red color filter layer) are combined to form a red light emitting element, an organic layer (light emitting unit) that emits white light and a color filter layer or the like that passes green light (or a protective layer that functions as a green color filter layer) are combined to form a green light emitting element, and an organic layer (light emitting unit) that emits white light and a color filter layer or the like that passes blue light (or a protective layer that functions as a blue color filter layer) are combined to form a blue light emitting element. One pixel (light emitting element unit) is composed of a combination of subpixels, such as a red light emitting element, a green light emitting element, and a blue light emitting element. In some cases, one pixel may be composed of a red light emitting element, a green light emitting element, a blue light emitting element, and a light emitting element that emits white light (or a light emitting element that emits complementary color light). In the form composed of at least two light emitting layers that emit different colors, there is a case in which the light emitting layers that emit different colors may be mixed and not clearly separated into the respective layers in practice. The organic layer may be shared by a plurality of light emitting elements or may be individually provided for each light emitting element, as described above.

When the protective layer has a function as a color filter layer, the protective layer may be made of a known color resist material. In the light emitting element that emits white light, a transparent filter layer may be disposed. With the protective layer also functioning as a color filter layer, the organic layer and the protective layer (color filter layer) come close to each other, and color mixture can be effectively prevented even with a widened angle of light emitted from the light emitting element, and viewing angle characteristics improve.

The organic layer may also be composed of one light emitting layer. In this case, the light emitting element may be composed of, for example, a red light emitting element having an organic layer including a red light emitting layer, a green light emitting element having an organic layer including a green light emitting layer, or a blue light emitting element having an organic layer including a blue light emitting layer. That is, the organic layer constituting the red light emitting element may emit red light, the organic layer constituting the green light emitting element may emit green light, and the organic layer constituting the blue light emitting element may emit blue light. One pixel is composed of these three light emitting elements (subpixels). In the case of a color display device, one pixel is composed of these three light emitting elements (subpixels). In principle, formation of a color filter layer is unnecessary, but a color filter layer may be provided for improving color purity.

When the light emitting element unit (one pixel) is composed of a plurality of light emitting elements (subpixels), the size of the light emitting region of the light emitting elements may be changed depending on the light emitting elements. Specifically, the size of the light emitting region of the third light emitting element (blue light emitting element) may be larger than the size of the light emitting region of the first light emitting element (red light emitting element) and the size of the light emitting region of the second light emitting element (green light emitting element). This allows the amount of light emission of the blue light emitting element to be larger than the amount of light emission of the red light emitting element and the amount of light emission of the green light emitting element, helps the blue light emitting element, the red light emitting element, and the green light emitting element have appropriate amounts of light emission, and can improve image quality. Alternatively, when a light emitting element unit (one pixel) composed of a white light emitting element that emits white light in addition to the red light emitting element, the green light emitting element, and the blue light emitting element is assumed, the size of the light emitting region of the green light emitting element and the size of the light emitting region of the white light emitting element are preferably larger than the size of the light emitting region of the red light emitting element and the size of the light emitting region of the blue light emitting element, from the viewpoint of luminance. The size of the light emitting region of the blue light emitting element is preferably larger than the size of the light emitting region of the red light emitting element, the size of the green light emitting element, and the size of the white light emitting element, from the viewpoint of the life of the light emitting element. However, the sizes of the light emitting regions are not limited to these configurations.

The component formed on the first substrate and the component formed on the second substrate are bonded by a bonding member in the display region. Examples of the material constituting the bonding member include thermosetting adhesives, such as acrylic adhesives, epoxy adhesives, urethane adhesives, silicone adhesives, and cyanoacrylate adhesives, and ultraviolet curable adhesives.

Examples of the material constituting the protective layer or the planarization layer include acrylic resins, epoxy resins, and various inorganic materials, such as SiO₂, SiN, SiON, SiC, amorphous silicon (α-Si), Al₂O₃, and TiO₂, and resist materials. The protective layer or the planarization layer may have a single layer configuration or may be formed of a plurality of layers. In the latter case, in the display device or the like of the present disclosure, it is preferable to sequentially reduce the value of the refractive index of the material constituting the protective layer or the planarization layer from the light incident direction toward the light emission direction. The protective layer or the planarization layer may be formed by known methods, such as various CVD methods, various coating methods, various PVD methods including a sputtering method and a vacuum vapor deposition method, and various printing methods such as a screen printing method. As a method for forming the protective layer, an atomic layer deposition (ALD) method may also be adopted. The protective layer and the planarization layer may be shared by a plurality of light emitting elements or may be individually provided for each light emitting element.

The base, the insulating layer, an interlayer insulating layer (described later), and an interlayer insulating material layer (described later) are formed in the display device. Examples of the insulating material constituting them include: SiOₓ-based materials (materials constituting a silicon-based oxide film), such as SiO₂, non-doped silicate glass (NSG), boron-phosphorus silicate glass (BPSG), PSG, BSG, AsSG, SbSG, PbSG, spin-on glass (SOG), low temperature oxide (LTO), low temperature CVD-SiO₂, low-melting-point glass, and glass paste; SiN-based materials including SiON-based materials; SiOC; SiOF; and SiCN. Examples of the material also include inorganic insulating materials, such as titanium oxide (TiO₂), tantalum oxide (Ta₂O₅), aluminum oxide (Al₂O₃), magnesium oxide (MgO), chromium oxide (CrOx), zirconium oxide (ZrO₂), niobium oxide (Nb₂O₅), tin oxide (SnO₂), and vanadium oxide (VOₓ). Examples of the material also include various resins, such as polyimide resins, epoxy resins, and acrylic resins, and low dielectric constant insulating materials, such as SiOCH, organic SOG, and fluorine-based resins (for example, a material having a dielectric constant k (=ε/ε₀) of, for example, 3.5 or less, and specific examples thereof include fluorocarbon, a cycloperfluorocarbon polymer, benzocyclobutene, a cyclic fluorine-based resin, polytetrafluoroethylene, amorphous tetrafluoroethylene, polyaryl ether, fluorinated aryl ether, fluorinated polyimide, amorphous carbon, parylene (polyparaxylylene), and fluorinated fullerene), Silk (coating-type low-dielectric-constant interlayer insulating film material, a trademark of The Dow Chemical Co.), and Flare (polyallyl ether (PAE)-based material, a trademark of Honeywell Electronic Materials Co.). These materials may be used alone or in appropriate combination. The insulating layer, the interlayer insulating layer, the interlayer insulating material layer, and the base may have a single layer structure or a stacked structure. The insulating layer, the interlayer insulating layer, the interlayer insulating material layer, and the base may be formed based on known methods, such as various CVD methods, various coating methods, various PVD methods including a sputtering method and a vacuum vapor deposition method, various printing methods such as a screen printing method, plating methods, electrodeposition methods, immersion methods, and sol-gel methods.

On the outermost surface (specifically, the outer surface of the second substrate) of the display device from which light is emitted, an ultraviolet absorbing layer, a contamination preventing layer, a hard coat layer, and an antistatic layer may be formed, or a protective member (for example, cover glass) may be disposed.

Although not limited, a light emitting element drive unit is provided beneath or below the base. The light emitting element drive unit may have a known circuit configuration, and it includes, for example, a transistor (specifically, for example, a MOSFET) formed on a silicon semiconductor substrate constituting the first substrate, or a thin film transistor (TFT) provided on various substrates constituting the first substrate. The transistor or the TFT constituting the light emitting element drive unit may be connected to the first electrode via a contact hole (contact plug) formed in the base. The second electrode may be connected to the light emitting element drive unit via a contact hole (contact plug) formed in the base in the outer periphery (specifically, the outer periphery of the pixel array unit) of the display device, for example. The alignment mark may be formed, for example, at the time of forming the wiring constituting the light emitting element driving unit.

The display device of the present disclosure may be used as, for example, a monitor device constituting a personal computer, or may be used as a monitor device incorporated in a television receiver, a mobile phone, a personal digital assistant (PDA), or a game device, or a display device incorporated in a projector. The display device may also be applied to an electronic view finder (EVF), a head mounted display (HMD), eyewear, AR glasses, or EVR, or may be applied to a display device for virtual reality (VR), mixed reality (MR), or augmented reality (AR). It is also possible to configure an image display device in an electronic book, an electronic paper such as an electronic newspaper, a bulletin board such as a signboard, a poster, or a blackboard, a rewritable paper as a substitute for printer paper, a display unit of a home appliance, a card display unit of a loyalty card or the like, an electronic advertisement, or an electronic POP advertisement. Various lighting devices including a backlight device for a liquid crystal display device and a planar light source device can be configured by using the display device of the present disclosure as a light emitting device.

### Example 1

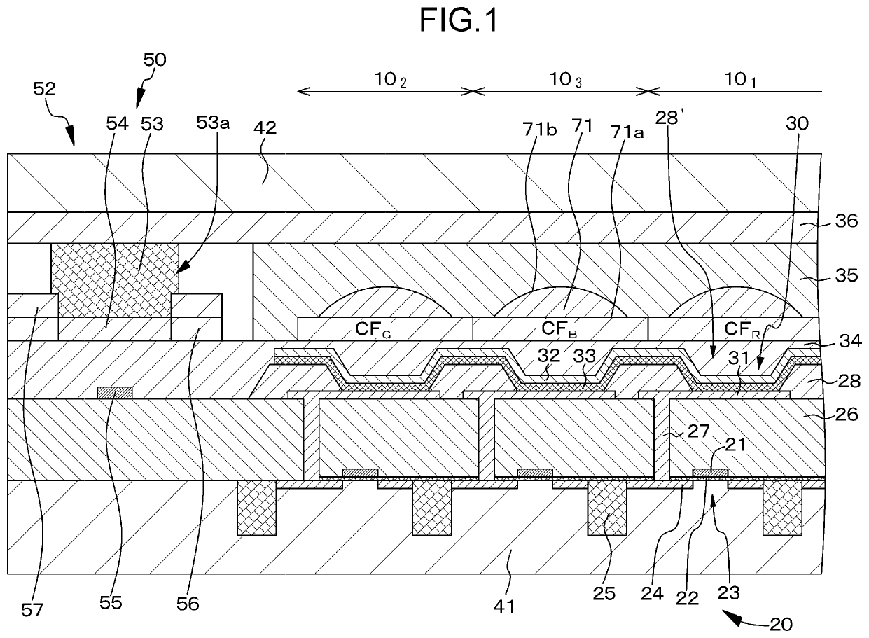

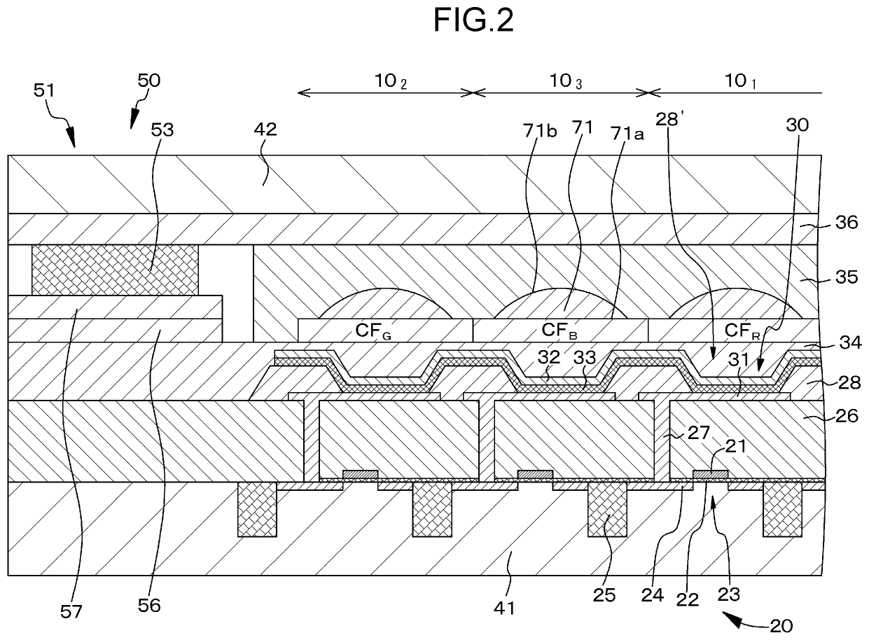

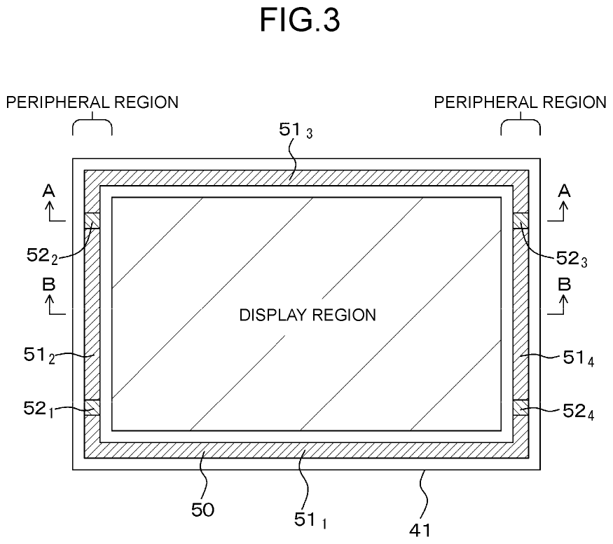

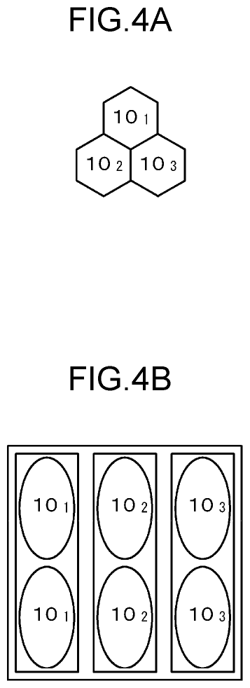

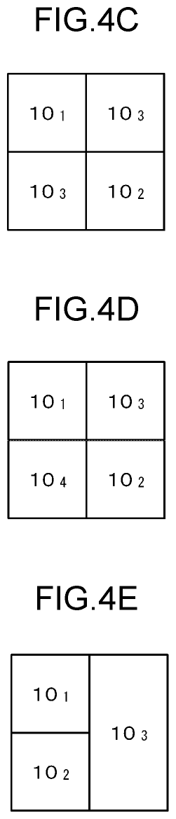

Example 1 relates to a display device of the present disclosure. FIG. 1 is a schematic and partial sectional view of the display device of Example 1 taken along the arrow A-A in FIG. 3. FIG. 2 is a schematic and partial sectional view of the display device of Example 1 taken along the arrow B-B in FIG. 3. FIG. 3 illustrates an arrangement state of a display region, a peripheral region, a first substrate, and a sealing part constituting the display device of Example 1. FIGS. 4A, 4B, 4C, 4D, and 4E each schematically illustrate an array of light emitting elements in a light emitting element unit constituting the display device of Example 1.

The display device of Example 1 includes:
a first substrate 41;
a second substrate 42 facing the first substrate 41;
a plurality of light emitting elements 10 provided in a display region sandwiched between the first substrate 41 and the second substrate 42; and
a sealing part 50 that is provided in a peripheral region sandwiched between the first substrate 41 and the second substrate 42 and surrounding the display region, the sealing part 50 sealing between the first substrate 41 and the second substrate 42. Then,
the sealing part 50 includes main sealing parts 51 and a sub sealing part 52 positioned between the main sealing part 51 and the main sealing part 51,
an alignment mark 55 is provided between the sub sealing part 52 and the first substrate 41 (see FIG. 1),
each main sealing part 51 has a stacked structure of light shielding member layers 56, 57 and a sealing member layer 53 from the first substrate side (see FIG. 2), and
the sub sealing part 52 has a stacked structure of a base material layer 54 formed of a non-light shielding member and the sealing member layer 53 from the first substrate side (see FIG. 1).

An extending part 53a of the sealing member layer 53 constituting the sub sealing part 52 is formed on the light shielding member layers 56, 57.

In the display device of Example 1, each light emitting element 10 includes a first electrode 31, an organic layer 33, a second electrode 32, and an optical path control unit 71 from the first substrate side, and the base material layer 54 is made of a material constituting the optical path control unit 71. That is, the display device of Example 1 is the display device of configuration 2-A. Further, the light emitting element 10 includes a color filter layer CF between the second electrode and the optical path control unit 71, and the light shielding member layers 56, 57 are made of a material constituting the color filter layer CF.

In the display device of Example 1, the plurality of light emitting elements 10 are classified into a plurality of types of light emitting elements. The display device includes a plurality of light emitting element units each including a plurality of types of light emitting elements 10. Specifically, one light emitting element 10 unit (pixel) is composed of three types of three light emitting elements 10 (subpixels). Then, in the display device of Example 1, light from the organic layer is emitted outside via the second substrate 42. That is, the display device of Example 1 is a top emission type display device that emits light from the second substrate 42.

In the display device of Example 1 or Examples 2 to 4 described later, one light emitting element unit (pixel) is composed of three light emitting elements (three subpixels) of a first light emitting element (red light emitting element) 10₁, a second light emitting element (green light emitting element) 10₂, and a third light emitting element (blue light emitting element) 10₃. The organic layer 33 constituting the first light emitting element 10₁, the organic layer 33 constituting the second light emitting element 10₂, and the organic layer 33 constituting the third light emitting element 10₃ emit white light as a whole. That is, the first light emitting element 10₁ that emits red light is formed of a combination of the organic layer 33 that emits white light and a red color filter layer CF_{R}. The second light emitting element 10₂ that emits green light is formed of a combination of the organic layer 33 that emits white light and a green color filter layer CF_{G}. The third light emitting element 10₃ that emits blue light is formed of a combination of the organic layer 33 that emits white light and a blue color filter layer CF_{B}. In some cases, in addition to the first light emitting element (red light emitting element) 10₁, the second light emitting element (green light emitting element) 10₂, and the third light emitting element (blue light emitting element) 10₃, a light emitting element (or a light emitting element that emits complementary color light) 10₄ that emits white color (or fourth color) may constitute the light emitting element unit (one pixel). The first light emitting element 10₁, the second light emitting element 10₂, and the third light emitting element 10₃ have substantially the same configuration and structure except for the configuration of the color filter layer, and in some cases, except for the arrangement position of the light emitting layer in the thickness direction of the organic layer. The number of pixels is, for example, 1920×1080, one light emitting element (display element) 10 constitutes one subpixel, and the number of light emitting elements (specifically, organic EL elements) 10 is three times the number of pixels.

In the display device of Example 1, the array of the subpixels may be a delta array as illustrated in FIG. 4A, a stripe array as illustrated in FIG. 4B, a diagonal array as illustrated in FIG. 4C, or a rectangle array. In some cases, as illustrated in FIG. 4D, one pixel may be composed of the first light emitting element 10₁, the second light emitting element 10₂, the third light emitting element 10₃, and a fourth light emitting element 10₄ that emits white light (or the fourth light emitting element that emits complementary color light). In the fourth light emitting element 10₄ that emits white light, a transparent filter layer may be provided instead of providing the color filter layer. A square array as illustrated in FIG. 4E may also be employed. The example illustrated in FIG. 4E satisfies (the area of the first light emitting element 10₁) (the area of the second light emitting element 10₂): (the area of the third light emitting element 10₃)=1:1:2, but it may be 1:1:1.

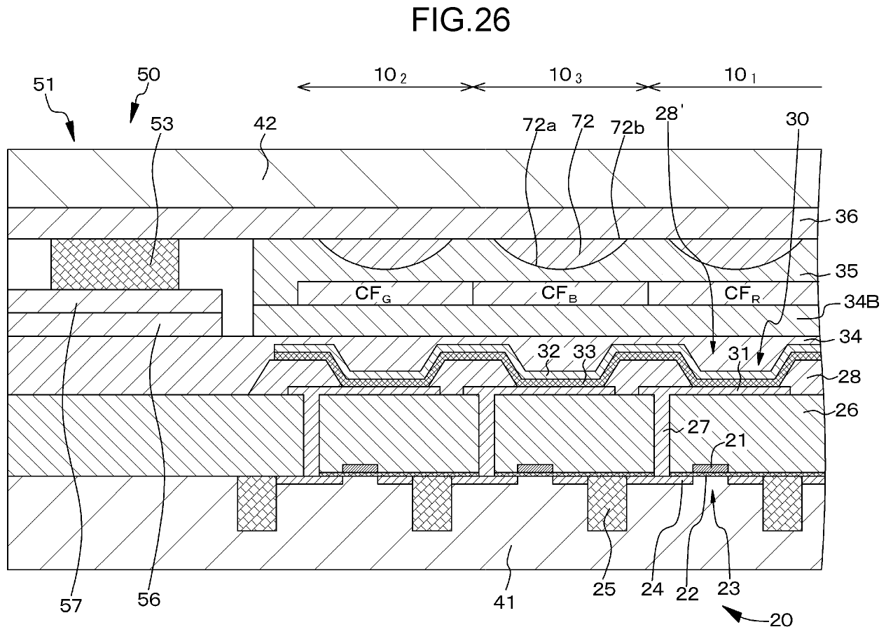

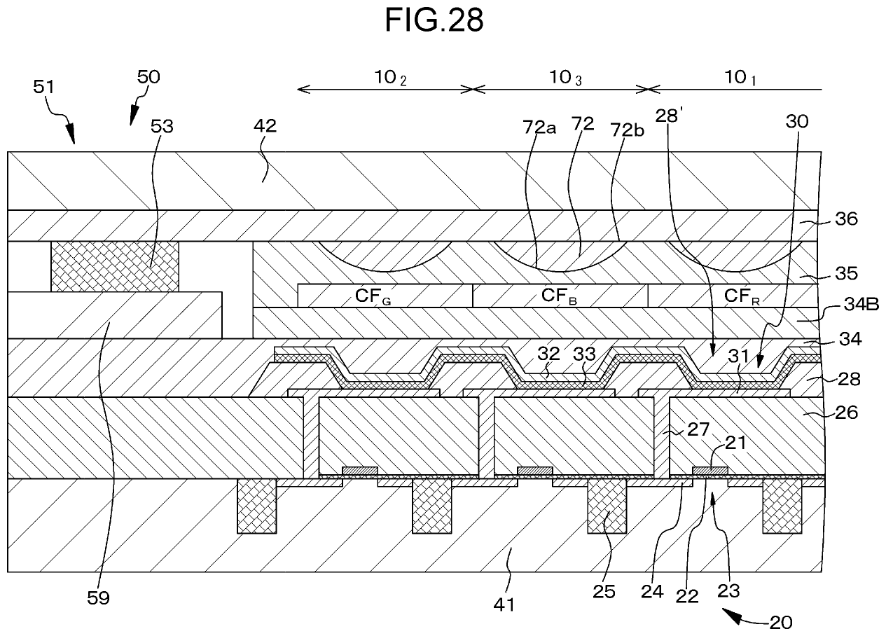

In the display device of Example 1 or Examples 2 to 4 described later, the array of the first light emitting element 10₁, the second light emitting element 10₂, and the third light emitting element 10₃ is specifically a delta array, but the array is not limited to the delta array. To simplify the drawings, the schematic and partial sectional views of the display device illustrated in FIGS. 1 and 2 and FIGS. 5, 6, 7, 8, 15, 16, 17, 18, 19, 20, 21, 22, 23, 24, 25, 26, 27, 28, 30, 33, and 38 described later are different from the schematic and partial sectional views of the display device in which the light emitting elements 10 are arrayed in a delta array.

In Example 1 or Examples 2 to 4 described later, the light emitting elements 10 may have a resonator structure in which the organic layer 33 serves as a resonance unit. To appropriately adjust the distance from the light emitting surface to the reflection surface (specifically, the distance from the light emitting surface to the first electrode 31 and the second electrode 32), the thickness of the organic layer 33 is preferably 8×10⁻⁸ m or more and 5×10⁻⁷ m or less, and more preferably 1.5×10⁻⁷ m or more and 3.5×10⁻⁷ m or less. In practice, in an organic EL display device having a resonator structure, the first light emitting element (red light emitting element) 10₁ causes light emitted from the light emitting layer to resonate, and emits reddish light (light having a light spectrum peak in a red region) from the second electrode 32. The second light emitting element (green light emitting element) 10₂ causes light emitted from the light emitting layer to resonate, and emits greenish light (light having a light spectrum peak in a green region) from the second electrode 32. The third light emitting element (blue light emitting element) 10₃ causes light emitted from the light emitting layer to resonate, and emits bluish light (light having a light spectrum peak in a blue region) from the second electrode 32.

The color filter layer CF is provided above the light emitting unit 30, and the optical path control unit 71 is provided on or above (above in the illustrated example) the color filter layer CF. The color filter layer CF is provided on the first substrate side. The first light emitting element 10₁ that emits red light includes a red color filter layer CF_{R}, the second light emitting element 10₂ that emits green light includes a green color filter layer CF_{G}, and the third light emitting element 10₃ that emits blue light includes a blue color filter layer CF_{B}.

External light toward the peripheral region and light reflected by the peripheral region are shielded by the light shielding member layers 56, 57. Examples of the material constituting the light shielding member layers 56, 57 include a material constituting the color filter layer. Specifically, the light shielding member layers 56, 57 have, for example, a stacked structure of the red color filter layer CF_{R} (in the drawings, designated by reference numeral 56) and the blue color filter layer CF_{B} (in the drawings, designated by reference numeral 57). However, the light shielding member layers are not limited to this structure, and a stacked structure of the red color filter layer CF_{R} and the green color filter layer CF_{G}, a stacked structure of the green color filter layer CF_{G} and the blue color filter layer CF_{B}, or a stacked structure of the red color filter layer CF_{R}, the green color filter layer CF_{G}, and the blue color filter layer CF_{B} may be employed. That is, the display device of Example 1 is the display device of configuration 1-A.

Specific examples of the material constituting the sealing member layer 53 include epoxy resins. A spherical spacer may be mixed in the material constituting the sealing member layer 53 to control the thickness of the main sealing part 51, for example.

The optical path control unit 71 is formed of a plano-convex lens having a convex shape in a direction away from the second electrode 32. A light emission surface 71b of the optical path control unit 71 has a convex shape, and a light incident surface 71a is flat. The optical path control unit 71 is formed of a part of a sphere, for example. The optical path control unit 71 is provided on the first substrate side. In this manner, the optical path control unit 71 has positive optical power, and light emitted from the light emitting unit 30 is focused by the optical path control unit 71. The planar shape of the optical path control unit 71 may be, for example, a circle, an ellipse, a regular hexagon, a square, or a rectangle, and the planar shape of the optical path control unit 71 may be the same shape, a similar shape, or an approximate shape as the light emitting region. The optical path control unit 71 may be made of, for example, a transparent resin material, such as an acrylic resin. As described above, the base material layer 54 is made of a material constituting the optical path control unit 71, that is, a transparent resin material, such as an acrylic resin.

The sealing part 50 includes a main sealing part (first sealing part) 51 and a sub sealing part (second sealing part) 52 positioned between the main sealing part 51 and the main sealing part 51. The number of sub sealing parts 52 may be two or more. In Example 1, the number of the sub sealing parts 52 is set to 4. As illustrated in FIG. 3, a first main sealing part 51₁, a first sub sealing part 52₁, a second main sealing part 51₂, a second sub sealing part 52₂, a third main sealing part 51₃, a third sub sealing part 52₃, a fourth main sealing part 51₄, a fourth sub sealing part 52₄, and a first main sealing part 51₁ are connected to form the sealing part 50. There is no gap between the main sealing part 51 and the sub sealing part 52. The sealing part 50 provided in the peripheral region surrounding the display region surrounds the display region in a frame shape.

The alignment mark 55 is provided between the sub sealing part 52 and the first substrate 41. Specifically, the alignment mark 55 may be formed of a metal layer provided on or above the first substrate 41. The alignment mark 55 is covered with, for example, an insulating material, and the sub sealing part 52 is provided on or above the insulating material. Specifically, in the illustrated example, the alignment mark 55 is covered with a protective layer 34, and the sub sealing part 52 is provided on the protective layer 34.

In the display device of Example 1 or Examples 2 to 4 described later, the light emitting element specifically includes:
a first electrode 31;
an organic layer 33 formed on the first electrode 31;
a second electrode 32 formed on the organic layer 33;
a protective layer 34 formed on the second electrode 32; and
a color filter layer CF (CF_{R}, CF_{G}, CF_{B}) formed on (or above) the protective layer 34. In Example 1, the light emitting element 10 and the color filter layers CF_{R}, CF_{G}, and CF_{B} are provided on the first substrate side. That is, the color filter layer CF is disposed above the second electrode 32, and the second substrate 42 is disposed above the color filter layer CF. In this manner, the color filter layer CF has an on-chip color filter layer structure (OCCF structure). This configuration can shorten the distance between the organic layer 33 and the color filter layer CF and can inhibit light emitted from the organic layer 33 from entering an adjacent color filter layer CF of another color to cause color mixture. The center of the color filter layer CF passes through the center of the light emitting region. Then, light from the organic layer 33 is emitted outside via the second electrode 32, the protective layer 34, the color filter layer CF, the optical path control unit 71, the bonding member 35, an underlayer 36, and the second substrate 42. The following description may be appropriately applied to Examples 2 to 4 described later in principle, except for the arrangement of the color filter layer CF.

The optical path control unit 71 and the color filter layer CF are bonded to the second substrate 42 (specifically, the underlayer 36 formed on the inner surface of the second substrate 42) by the bonding member 35.

Here, n₀≥n₁>n₂
is satisfied where
n₁ is the refractive index of a material constituting the optical path control unit 71, n₀ is the refractive index of a material constituting the color filter layer CF, and n₂ is the refractive index of the bonding member 35 made of an acrylic adhesive. Specifically,
n₀=1.7
n₁=1.6
n₂=1.35

are satisfied. The acrylic resin constituting the optical path control unit 71 and the acrylic adhesive constituting the bonding member 35 are different from each other.

A light emitting element drive unit (drive circuit) is provided below a base 26 made of an insulating material formed on the basis of a CVD method. The light emitting element drive unit may have a known circuit configuration. The light emitting element drive unit is composed of a transistor (specifically, a MOSFET) formed on a silicon semiconductor substrate corresponding to the first substrate 41. The transistor 20 composed of a MOSFET includes a gate insulating layer 22 formed on the first substrate 41, a gate electrode 21 formed on the gate insulating layer 22, source/drain regions 24 formed on the first substrate 41, a channel formation region 23 formed between the source/drain regions 24, and an element isolation region 25 surrounding the channel formation region 23 and the source/drain regions 24. The transistor 20 and the first electrode 31 are electrically connected via a contact plug 27 provided in the base 26. In the drawings, one transistor 20 is illustrated for one light emitting element drive unit. Examples of the material constituting the base 26 include SiO₂, SiN, and SiON.

The light emitting unit 30 is provided on the base 26. Specifically, the first electrode 31 of each light emitting element 10 is provided on the base 26. An insulating layer 28 having an opening 28′ in which the first electrode 31 is exposed at the bottom is formed on the base 26, and the organic layer 33 is formed at least on the first electrode 31 exposed at the bottom of the opening 28′. Specifically, the organic layer 33 is formed from the top of the first electrode 31 exposed at the bottom of the opening 28′ to the top of the insulating layer 28, and the insulating layer 28 is formed from the first electrode 31 to the top of the base 26. The part of the organic layer 33 that actually emits light is surrounded by the insulating layer 28. That is, the light emitting region includes the first electrode 31 and a region of the organic layer 33 formed on the first electrode 31, and it is provided on the base 26. In other words, the region of the organic layer 33 surrounded by the insulating layer 28 corresponds to the light emitting region. The insulating layer 28 and the second electrode 32 are covered with the protective layer 34 made of SiN. The color filter layer CF (CF_{R}, CF_{G}, CF_{B}) made of a known material is formed on the protective layer 34 by a known method, and the color filter layer CF is formed on the protective layer 34.

The first electrode 31 functions as an anode electrode, and the second electrode 32 functions as a cathode electrode. The first electrode 31 is formed of a light reflection material layer, specifically, for example, an Al—Nd alloy layer, an Al—Cu alloy layer, or a stacked structure of an Al—Ti alloy layer and an ITO layer, and the second electrode 32 is made of a transparent conductive material, such as ITO. The first electrode 31 is formed on the base 26 based on a combination of a vacuum vapor deposition method and an etching method. The second electrode 32 is formed by a film forming method in which the energy of film-forming particles is small, such as a vacuum vapor deposition method, and the electrode is not patterned. That is, the second electrode 32 is a common electrode for the plurality of light emitting elements 10, and it is a so-called solid electrode. The second electrode 32 is connected to the light emitting element drive unit via a contact hole (contact plug) not illustrated but formed in the base 26 at the outer periphery (specifically, the outer periphery of the pixel array unit) of the display device. In the outer periphery of the display device, an auxiliary electrode connected to the second electrode 32 may be provided below the second electrode 32, and the auxiliary electrode may be connected to the light emitting element drive unit. The organic layer 33 is not patterned either. That is, the organic layer 33 is shared by the plurality of light emitting elements 10. However, the organic layer 33 is not limited to this configuration, and the organic layer 33 may be provided independently for each light emitting element 10. The first substrate 41 is composed of a silicon semiconductor substrate, and the second substrate 42 is formed of a glass substrate.

In Example 1, the organic layer 33 has a stacked structure of a hole injection layer (HIL), a hole transport layer (HTL), a light emitting layer, an electron transport layer (ETL), and an electron injection layer (EIL). The light emitting layer includes at least two light emitting layers that emit different colors, and the light emitted from the organic layer 33 is white light. Specifically, the organic layer has a structure in which three layers of a red light emitting layer that emits red light, a green light emitting layer that emits green light, and a blue light emitting layer that emits blue light are stacked. The organic layer may have a structure in which two layers of a blue light emitting layer that emits blue light and a yellow light emitting layer that emits yellow light are stacked (emitting white light as a whole), or a structure in which two layers of a blue light emitting layer that emits blue light and an orange light emitting layer that emits orange light are stacked (emitting white light as a whole). As described above, the first light emitting element 10₁ to display red is provided with the red color filter layer CF_{R}, the second light emitting element 10₂ to display green is provided with the green color filter layer CF_{G}, and the third light emitting element 10₃ to display blue is provided with the blue color filter layer CF_{B}.

The hole injection layer is a layer that improves hole injection efficiency and functions as a buffer layer that prevents leakage. The hole injection layer has a thickness of, for example, about 2 nm to 10 nm. The hole injection layer is made of, for example, a hexaazatriphenylene derivative represented by the following Formula (A) or Formula (B). When an end surface of the hole injection layer contacts the second electrode, it becomes a main cause of occurrence of luminance variation between pixels, leading to deterioration of display image quality.

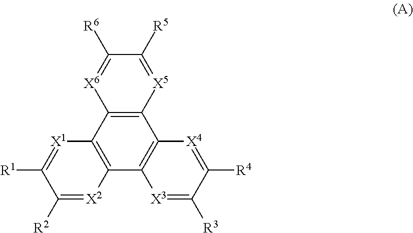

Here, R¹ to R⁶ are each independently a substituent selected from hydrogen, halogen, a hydroxy group, an amino group, an arylamino group, a substituted or unsubstituted carbonyl group having 20 or less carbon atoms, a substituted or unsubstituted carbonyl ester group having 20 or less carbon atoms, a substituted or unsubstituted alkyl group having 20 or less carbon atoms, a substituted or unsubstituted alkenyl group having 20 or less carbon atoms, a substituted or unsubstituted alkoxy group having 20 or less carbon atoms, a substituted or unsubstituted aryl group having 30 or less carbon atoms, a substituted or unsubstituted heterocyclic group having 30 or less carbon atoms, a nitrile group, a cyano group, a nitro group, or a silyl group, and adjacent R^{m} (m=1 to 6) may be bonded to each other via a cyclic structure. X¹ to X⁶ are each independently a carbon atom or a nitrogen atom.

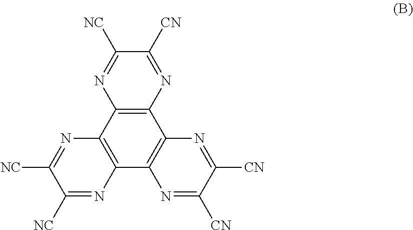 [SMILES: N#Cc1nc2c3nc(C#N)c(C#N)nc3c3nc(C#N)c(C#N)nc3c2nc1C#N]

The hole transport layer is a layer that improves hole transport efficiency to the light emitting layer. In the light emitting layer, application of an electric field causes electrons and holes to recombine and generate light. The electron transport layer is a layer that improves electron transport efficiency to the light emitting layer, and the electron injection layer is a layer that improves electron injection efficiency to the light emitting layer.

The hole transport layer is made of, for example, 4, 4′,4″-tris (3-methylphenylphenylamino) triphenylamine (m-MTDATA) or α-naphthylphenyldiamine (αNPD) having a thickness of about 40 nm.

The light emitting layer is a light emitting layer that generates white light through color mixture, and it is formed by, for example, stacking a red light emitting layer, a green light emitting layer, and a blue light emitting layer, as described above.

In the red light emitting layer, application of an electric field causes some of the holes injected from the first electrode 31 and some of the electrons injected from the second electrode 32 to recombine and generate red light. Such a red light emitting layer contains, for example, at least one material among a red light emitting material, a hole transporting material, an electron transporting material, and a both charge transporting material. The red light emitting material may be a fluorescent material or a phosphorescent material. The red light emitting layer having a thickness of about 5 nm is made of a material formed by mixing 30 mass % of 2,6-bis[(4′-methoxydiphenylamino)styryl]-1,5-dicyanonaphthalene (BSN) with 4,4-bis(2,2-diphenylvinyl)biphenyl (DPVBi), for example.

In the green light emitting layer, application of an electric field causes some of the holes injected from the first electrode 31 and some of the electrons injected from the second electrode 32 to recombine and generate green light. Such a green light emitting layer contains, for example, at least one material among a green light emitting material, a hole transporting material, an electron transporting material, and a both charge transporting material. The green light emitting material may be a fluorescent material or a phosphorescent material. The green light emitting layer having a thickness of about 10 nm is made of a material formed by mixing 5 mass % of coumarin 6 with DPVBi, for example.

In the blue light emitting layer, application of an electric field causes some of the holes injected from the first electrode 31 and some of the electrons injected from the second electrode 32 to recombine and generate blue light. Such a blue light emitting layer contains, for example, at least one material among a blue light emitting material, a hole transporting material, an electron transporting material, and a both charge transporting material. The blue light emitting material may be a fluorescent material or a phosphorescent material. The blue light emitting layer having a thickness of about 30 nm is made of a material formed by mixing 2.5 mass % of 4,4′-bis[2-{4-(N,N-diphenylamino)phenyl}vinyl]biphenyl (DPAVBi) with DPVBi, for example.

The electron transport layer having a thickness of about 20 nm is made of, for example, 8-hydroxyquinoline aluminum (Alq3). The electron injection layer having a thickness of about 0.3 nm is made of, for example, LiF or Li₂O.

The materials constituting each layer are merely examples and are not limited to these materials. Forming the light emitting layer by using a phosphorescent material can increase the luminance about 2.5 times to 3 times as compared with forming the light emitting layer by using a fluorescent material. The light emitting layer may also be made of a thermally activated delayed fluorescence (TADF) material. The light emitting layer may be composed of a blue light emitting layer and a yellow light emitting layer or may be composed of a blue light emitting layer and an orange light emitting layer, for example.

In a broad sense, the first substrate 41 or the second substrate 42 may be composed of a silicon semiconductor substrate, a high strain point glass substrate, a soda glass (Na₂O·CaO·SiO₂) substrate, a borosilicate glass (Na₂O·B₂O₃·SiO₂) substrate, a forsterite (2MgO·SiO₂) substrate, a lead glass (Na₂O·PbO·SiO₂) substrate, various glass substrates having an insulating material layer formed on the surface thereof, a quartz substrate, a quartz substrate having an insulating material layer formed on the surface thereof, or an organic polymer (having a form of a polymer material such as a flexible plastic film, a plastic sheet, or a plastic substrate made of a polymer material) exemplified by polymethyl methacrylate (PMMA), polyvinyl alcohol (PVA), polyvinylphenol (PVP), polyethersulfone (PES), polyimide, polycarbonate, polyethylene terephthalate (PET), and polyethylene naphthalate (PEN). The materials constituting the first substrate 41 and the second substrate 42 may be the same or different. Since the display device of the present disclosure is a top emission type display device, the second substrate 42 is required to be transparent to light from the light emitting element 10.

In a broad sense, when the first electrode functions as an anode electrode, examples of the material constituting the first electrode include a metal having a high work function, such as platinum (Pt), gold (Au), silver (Ag), chromium (Cr), tungsten (W), nickel (Ni), copper (Cu), iron (Fe), cobalt (Co), or tantalum (Ta), and an alloy, such as an Ag—Pd—Cu alloy containing silver as a main component and containing 0.3 mass % to 1 mass % of palladium (Pd) and 0.3 mass % to 1 mass % of copper (Cu), an Al—Nd alloy, an Al—Cu alloy, or an Al—Cu—Ni alloy. When a conductive material having a small work function value and a high light reflectance, such as aluminum (Al) and an alloy containing aluminum, is used, the conductive material may be used as an anode electrode by improving hole injection characteristics by providing an appropriate hole injection layer or the like. The thickness of the first electrode may be 0.1 μm to 1 μm, for example. When a light reflection layer constituting a resonator structure to be described later is provided, the first electrode is required to be transparent to light from the light emitting element 10. Thus, examples of the material constituting the first electrode include various transparent conductive materials, such as transparent conductive materials containing, as a base layer, indium oxide, indium-tin oxide (ITO, including Sn-doped In₂O₃, crystalline ITO, and amorphous ITO), indium-zinc oxide (IZO), indium-gallium oxide (IGO), indium-doped gallium-zinc oxide (IGZO, In—GaZnO₄), IFO (F-doped In₂O₃), ITiO (Ti-doped In₂O₃), InSn, InSnZnO, tin oxide (SnO₂), ATO (Sb-doped SnO₂), FTO (F-doped SnO₂), zinc oxide (ZnO), aluminum oxide-doped zinc oxide (AZO), gallium-doped zinc oxide (GZO), B-doped ZnO, AlMgZnO (aluminum oxide and magnesium oxide-doped zinc oxide), antimony oxide, titanium oxide, NiO, spinel-type oxide, oxide having a YbFe₂O₄ structure, gallium oxide, titanium oxide, niobium oxide, nickel oxide, or the like. The first electrode may also have a structure in which a transparent conductive material having excellent hole injection characteristics, such as an oxide of indium and tin (ITO) or an oxide of indium and zinc (IZO), is stacked on a dielectric multilayer film or a reflective film having high light reflectivity, such as aluminum (Al) or an alloy thereof (for example, Al—Cu—Ni alloy). When the first electrode functions as a cathode electrode, the first electrode is desirably made of a conductive material having a small work function value and a high light reflectance. The first electrode may be used as a cathode electrode by improving electron injection characteristics by providing an appropriate electron injection layer in a conductive material having a high light reflectance used as an anode electrode.

In a broad sense, when the second electrode functions as a cathode electrode, the material (semi-light transmitting material or light transmitting material) constituting the second electrode is desirably made of a conductive material that transmits emitted light and has a small work function value to efficiently inject electrons into the organic layer (light emitting layer). Examples thereof include a metal and an alloy having a small work function, such as aluminum (Al), silver (Ag), magnesium (Mg), calcium (Ca), sodium (Na), strontium (Sr), an alloy of an alkali metal or an alkaline earth metal and silver (Ag), such as an alloy of magnesium (Mg) and silver (Ag) (Mg—Ag alloy), an alloy of magnesium and calcium (Mg—Ca alloy), or an alloy of aluminum (Al) and lithium (Li) (Al—Li alloy). Of these, a Mg—Ag alloy is preferable, and the volume ratio between magnesium and silver may be, for example, Mg:Ag=5:1 to 30:1. The volume ratio between magnesium and calcium may be, for example, Mg:Ca=2:1 to 10:1. The thickness of the second electrode may be, for example, 4 nm to 50 nm, preferably 4 nm to 20 nm, more preferably 6 nm to 12 nm. Examples of the material of the second electrode also include at least one material selected from the group consisting of Ag—Nd—Cu, Ag—Cu, Au, and Al—Cu. The second electrode may also have a stacked structure of the above-described material layer and a so-called transparent electrode (for example, having a thickness of 3×10⁻⁸ m to 1×10⁻⁶ m) made of, for example, ITO or IZO from the organic layer side. A bus electrode (auxiliary electrode) made of a low-resistance material, such as aluminum, an aluminum alloy, silver, a silver alloy, copper, a copper alloy, gold, or a gold alloy may be provided to the second electrode to reduce the resistance of the second electrode as a whole. The average light transmittance of the second electrode is desirably 50% to 90%, and preferably 60% to 90%. When the second electrode functions as an anode electrode, the second electrode is desirably composed of a conductive material that transmits emitted light and has a large work function value.

Examples of a method for forming the first electrode and the second electrode include: vapor deposition methods including an electron beam vapor deposition method, a hot filament vapor deposition method, and a vacuum vapor deposition method; sputtering methods; chemical vapor deposition methods (CVD methods); MOCVD methods; a combination of an ion plating method and an etching method; various printing methods such as a screen printing method, an inkjet printing method, and a metal mask printing method; plating methods, such as electroplating method and electroless plating method; lift-off methods; laser ablation methods; and sol-gel methods. With various printing methods and plating methods, it is possible to directly form the first electrode and the second electrode having a desired shape (pattern). When the second electrode is formed after the organic layer is formed, it is particularly preferable to form the second electrode based on a film forming method in which the energy of film-forming particles is small, such as a vacuum vapor deposition method, or a film forming method, such as an MOCVD method, from the viewpoint of preventing occurrence of damage to the organic layer. When the organic layer is damaged, there is a possibility that a non-light emitting pixel (or a non-light emitting subpixel) called a “dot” is generated because of generation of a leakage current.

Hereinafter, an outline of a method for producing the display device of Example 1 illustrated in FIGS. 1 and 2 will be described.

[Step-100]

First, form a light emitting element drive unit on a silicon semiconductor substrate (the first substrate 41) based on a known MOSFET production process.

[Step-110]

Next, form the base 26 on the entire surface based on a CVD method.

[Step-120]

Next, form a connection hole in the part of the base 26 positioned above one of the source/drain regions of the transistor 20 based on a photolithography technique and an etching technique. Thereafter, form a metal layer on the base 26 including the connection hole based on, for example, a sputtering method, and then pattern the metal layer based on a photolithography technique and an etching technique, to form the first electrode 31 on a part of the base 26. The first electrode 31 is separated for each light emitting element. A contact hole (contact plug) 27 that electrically connects the first electrode 31 and the transistor 20 may be formed in the connection hole at the same time. The alignment mark 55 may be formed on a part of the base 26 (specifically, on a part of the base 26 positioned below the region where the sub sealing part 52 is to be formed).

[Step-130]

Then, after the insulating layer 28 is formed on the entire surface based a CVD method, for example, form the opening 28′ in a part of the insulating layer 28 on the first electrode 31 based on a photolithography technique and an etching technique. The first electrode 31 is exposed at the bottom of the opening 28′.

[Step-140]

Next, form the organic layer 33 on the first electrode 31 and the insulating layer 28 through, for example, a PVD method such as a vacuum vapor deposition method or a sputtering method, or a coating method such as a spin coating method or a die coating method. Next, form the second electrode 32 on the entire surface based on, for example, a vacuum vapor deposition method. In this manner, the organic layer 33 and the second electrode 32 may be formed on the first electrode 31. The organic layer 33 may be patterned into a desired shape in some cases.

[Step-150]

Thereafter, form the protective layer 34 on the entire surface though, for example, a CVD method, a PVD method, or a coating method, and perform a planarization treatment on the top surface of the protective layer 34. Forming the protective layer 34 based on a coating method has few in-process restrictions and has wide selection of material, with which a high refractive index material can be used. Then, form the color filter layer CF (CF_{R}, CF_{G}, CF_{B}) on the protective layer 34 based on a known method.

In addition, form the light shielding member layers 56, 57 (color filter layers CF_{R}, CF_{B}) on the protective layer 34, then remove the light shielding member layers 56, 57 from the portion where the sub sealing part 52 is to be disposed but leave the light shielding member layers 56, 57 at the portion where the main sealing part 51 is to be disposed.

[Step-160]

Next, form a resist material layer for forming the optical path control unit 71 on the color filter layer CF (CF_{R}, CF_{G}, CF_{B}). Then, pattern the resist material layer and further, perform a heat treatment (reflow treatment) thereon to form the resist material layer into a lens shape. The optical path control unit 71 (lens member) may be thus obtained. In the formation of the optical path control unit 71 (lens member), refer to the alignment mark 55 to define the formation position of the optical path control unit 71 (lens member).

In addition, leave the base material layer 54 formed of the lens formation layer (the base material layer 54 formed of the non-light shielding member) on the protective layer 34 exposed at the portion where the sub sealing part 52 is to be provided.

[Step-170]

To provide the sealing part 50 (the main sealing part 51 and the sub sealing part 52), form the sealing member layer 53 in a desired region of the second substrate 42 based on, for example, a printing method or a coating method. Then, bond the first substrate 41 and the second substrate 42, specifically, bond the color filter layer CF and the optical path control unit 71 to the underlayer 36 formed on the inner surface of the second substrate 42 via the bonding member (sealing resin layer) 35. At the same time, in the main sealing part 51, bond the sealing member layer 53 and the light shielding member layers 56, 57, and in the sub sealing part 52, bond the sealing member layer 53 and the base material layer 54, and further, bond the extending part 53a of the sealing member layer 53 and the light shielding member layers 56, 57. The display device (organic EL display device) illustrated in FIGS. 1 and 2 may be thus obtained.

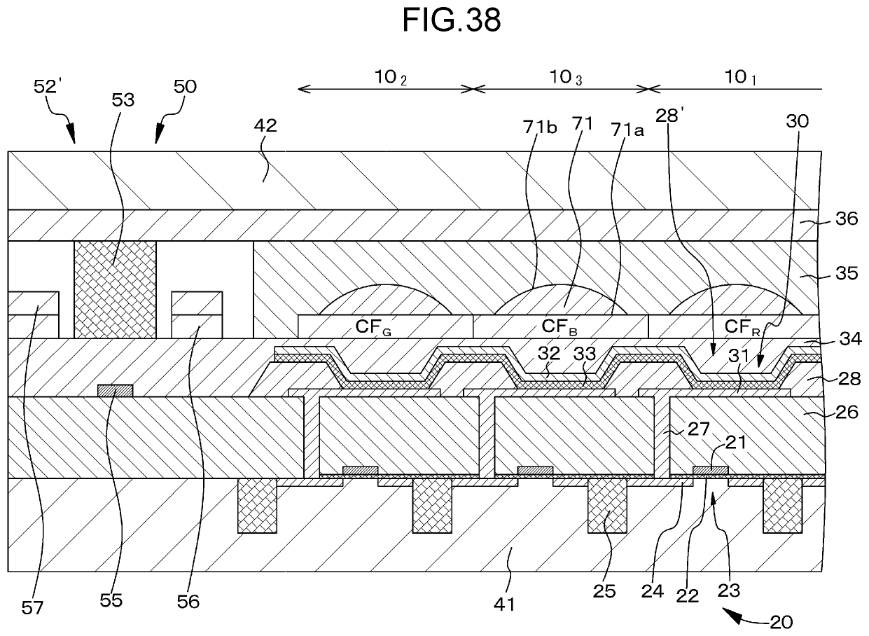

When the base material layer 54 is not provided, the sealing member layer 53 is directly bonded to the protective layer 34 in the sub sealing part 52′ as FIG. 38 illustrates a schematic and partial sectional view of a reference example of a display device similar to a view taken along the arrow A-A in FIG. 3. As a result, in the sub sealing part 52′, the width of the sealing member layer 53 is narrowed, and the sealing member layer 53 and the light shielding member layers 56, 57 cannot be bonded to each other. This causes a decrease in the reliability of the display device, and in the worst case, a discontinuous part may be generated in the sealing member layer at the sub sealing part 52′.

In the display device of Example 1, the alignment mark is not hidden by the light shielding member layer, and the alignment mark can be easily and reliably detected. Moreover, since the sub sealing part has a stacked structure of the base material layer formed of the non-light shielding member and the sealing member layer from the first substrate side, the width of the sealing member layer is not narrowed, the extending part of the sealing member layer and the light shielding member layer can be bonded to each other, which can impart high reliability to the display device, and a discontinuous part is not generated in the sealing member layer at the sub sealing part.

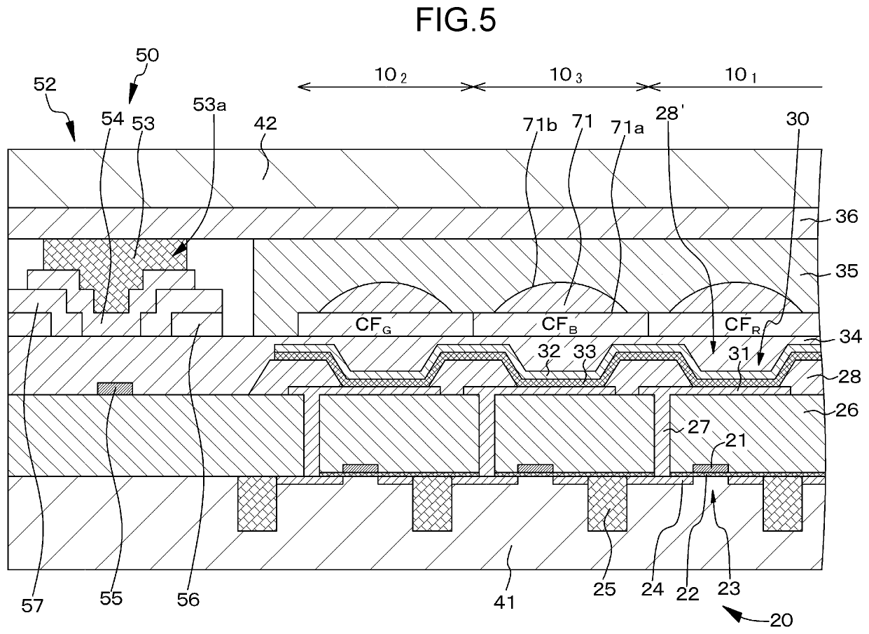

FIG. 5 is a schematic and partial sectional view of Modification-1 of the display device of Example 1 taken along the arrow A-A in FIG. 3. The display device may have a structure in which the light shielding member layer 56 (color filter layer CF_{R}) is covered with the light shielding member layer 57 (color filter layer CF_{R}) and the light shielding member layer 57 (color filter layer CF_{R}) is covered with the base material layer 54.

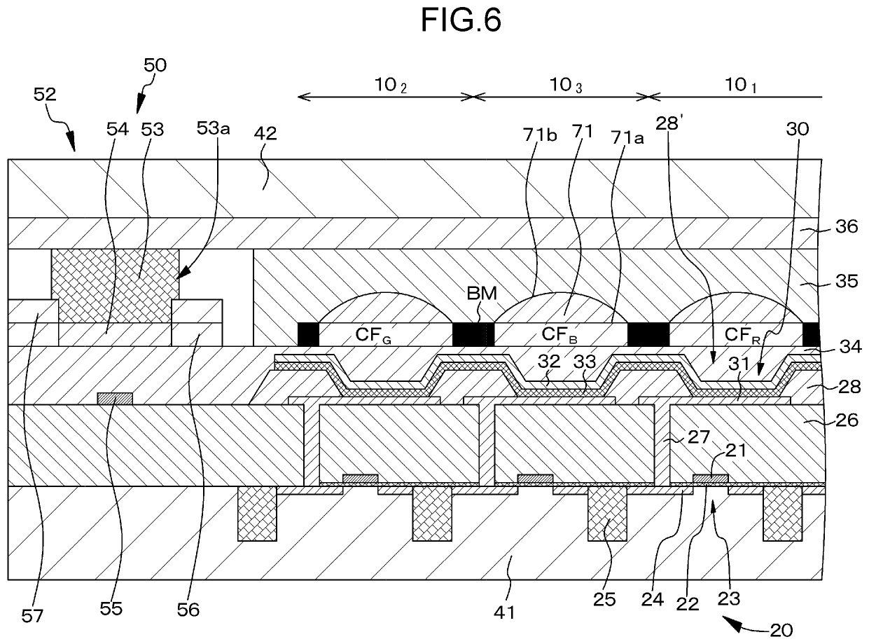

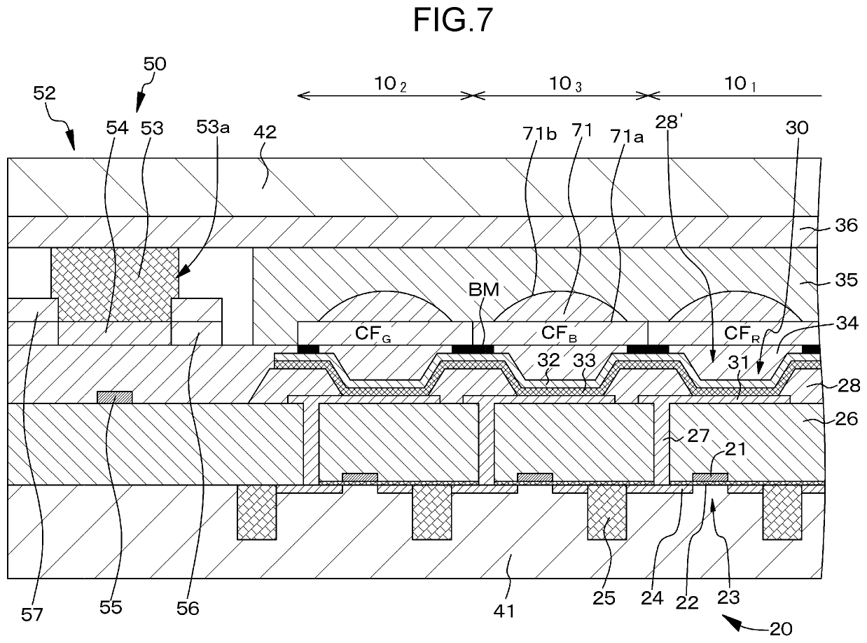

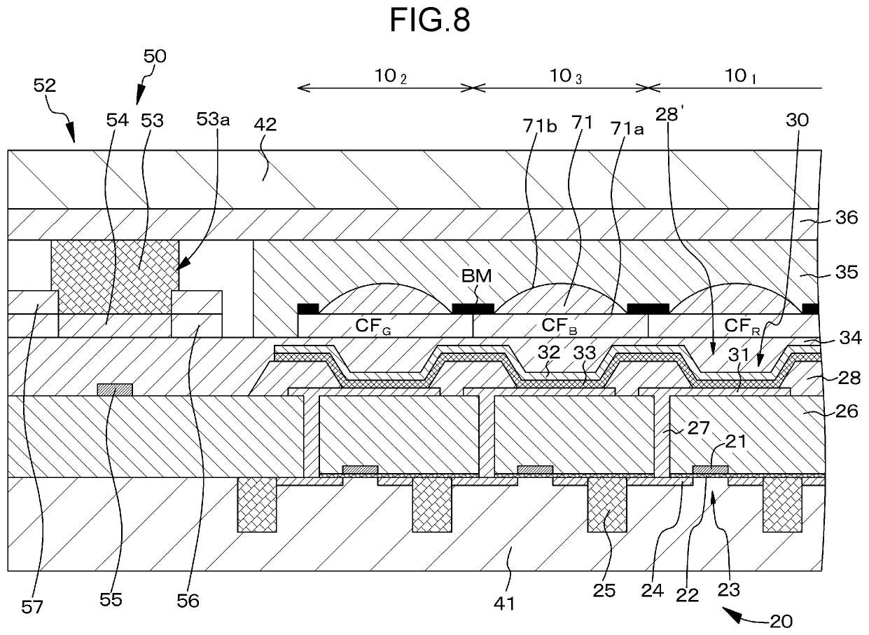

In addition, as FIG. 6 illustrates a schematic and partial sectional view of Modification-2 of the light emitting element of Example 1 taken along the arrow A-A in FIG. 3, a light absorbing layer (black matrix layer) BM may be formed between the color filter layers CF of adjacent light emitting elements. As FIG. 7 illustrates a schematic and partial sectional view of Modification-3 of the display device of Example 1 taken along the arrow A-A in FIG. 3, the light absorbing layer (black matrix layer) BM may be formed below the position between the color filter layers CF of adjacent light emitting elements. As FIG. 8 illustrates a schematic and partial sectional view of Modification-4 of the display device of Example 1 taken along the arrow A-A in FIG. 3, the light absorbing layer (black matrix layer) BM may be formed between the optical path control unit 71 and the optical path control unit 71 of adjacent light emitting elements. The black matrix layer BM is formed of, for example, a black resin film (specifically, for example, a black polyimide-based resin) mixed with a black colorant and having an optical density of 1 or more. These Modification-2, Modification-3, and Modification-4 may be appropriately applied to Modification-1, and they may also be applied to other Examples.

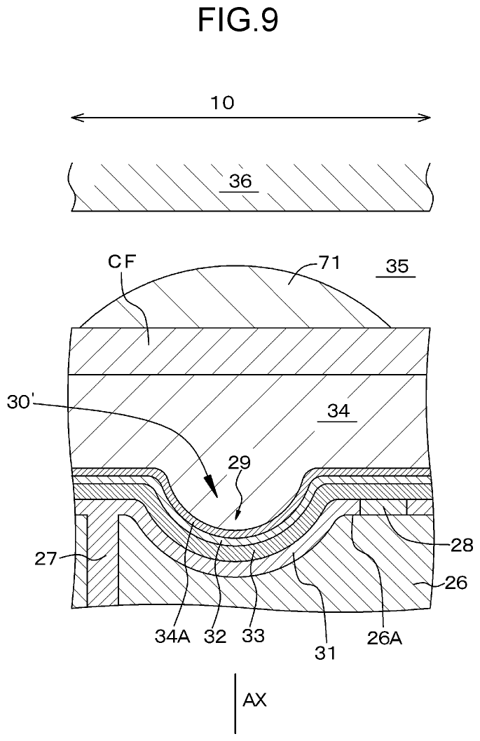

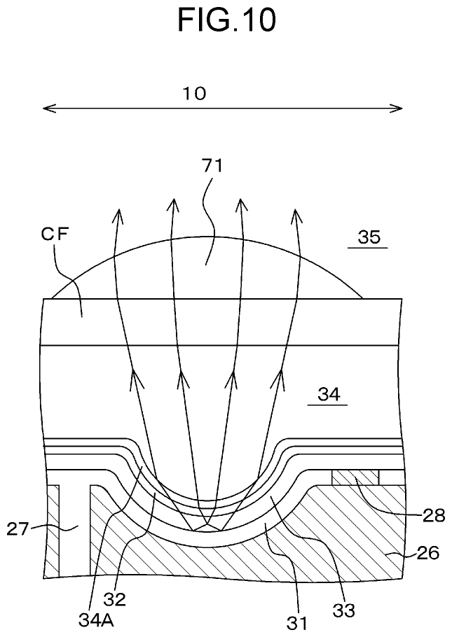

FIG. 9 is a schematic and partial sectional view of the light emitting element constituting Modification-5 of the display device of Example 1, and FIG. 10 is a schematic and partial sectional view of the light emitting element for explaining the behavior of light from the light emitting element constituting Modification-5 of the display device of Example 1.

In the light emitting element 10 constituting Modification-5 of the display device of Example 1, a light emitting unit 30′ has a convex shape toward the first substrate 41. Specifically,
a surface 26A of the base 26 is provided with a recess 29,
at least a part of the first electrode 31 is formed following the shape of the top surface of the recess 29,
at least a part of the organic layer 33 is formed on the first electrode 31 following the shape of the top surface of the first electrode 31,
the second electrode 32 is formed on the organic layer 33 following the shape of the top surface of the organic layer 33, and
the protective layer 34 is formed on the second electrode 32.

In the light emitting element of Modification-5, in the recess 29, the entire first electrode 31 is formed following the shape of the top surface of the recess 29, and the entire organic layer 33 is formed on the first electrode 31 following the shape of the top surface of the first electrode 31.

In the light emitting element 10 in Modification-5, although not essential, a second protective layer 34A may be formed between the second electrode 32 and the protective layer 34. The second protective layer 34A is formed following the shape of the top surface of the second electrode 32. Here, n₃>n₄ is satisfied where the refractive index of the material constituting the protective layer 34 is n₃, and the refractive index of the material constituting the second protective layer 34A is n₄. Examples of the value of (n₃−n₄) include, but are not limited to, 0.1 to 0.6. Specifically, the material constituting the protective layer 34 includes a material in which TiO₂ is added to a base material made of an acrylic resin to adjust (enhance) the refractive index or a material in which TiO₂ is added to a base material made of the same type of material as the color resist material (a colorless transparent material to which n₀ pigment is added) to adjust (enhance) the refractive index, and the material constituting the second protective layer 34A includes SiN, SiON, Al₂O₃, or TiO₂. For example,
n₃=2.0
n₄=1.8

are satisfied. Forming such a second protective layer 34A allows part of light emitted from the organic layer 33 to pass through the second electrode 32 and the second protective layer 34A and enter the protective layer 34, and part of light emitted from the organic layer 33 to be reflected by the first electrode 31, pass through the second electrode 32 and the second protective layer 34A, and enter the protective layer 34, as illustrated in FIG. 10. In this manner, as a result of formation of an internal lens with the second protective layer 34A and the protective layer 34, light emitted from the organic layer 33 can be collected in a direction toward the central part of the light emitting element.

Alternatively, in the light emitting element of Modification-5, when an incident angle of light emitted from the organic layer 33 and incident on the protective layer 34 through the second electrode 32 is θᵢ, and a refraction angle of light incident on the protective layer 34 is θᵣ,

|θ₁|>|θᵣ|

is satisfied, where |θᵣ|≠0. Satisfying such a condition allows part of light emitted from the organic layer 33 to pass through the second electrode 32 and enter the protective layer 34, and part of light emitted from the organic layer 33 to be reflected by the first electrode 31, pass through the second electrode 32, and enter the protective layer 34. As a result of forming an internal lens in this manner, light emitted from the organic layer 33 can be collected in a direction toward the central part of the light emitting element.

Forming the recess as described above can further improve the front light extraction efficiency as compared with a case where the first electrode, the organic layer, and the second electrode have a flat stacked structure.

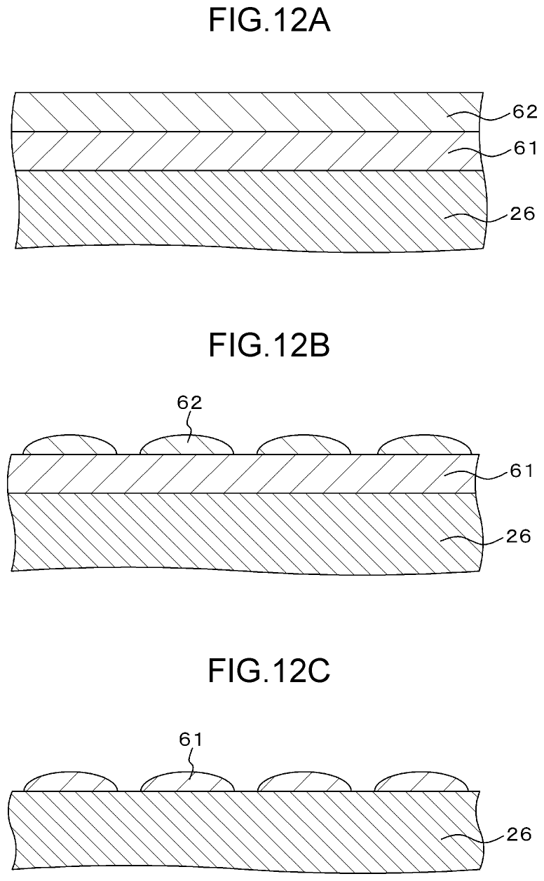

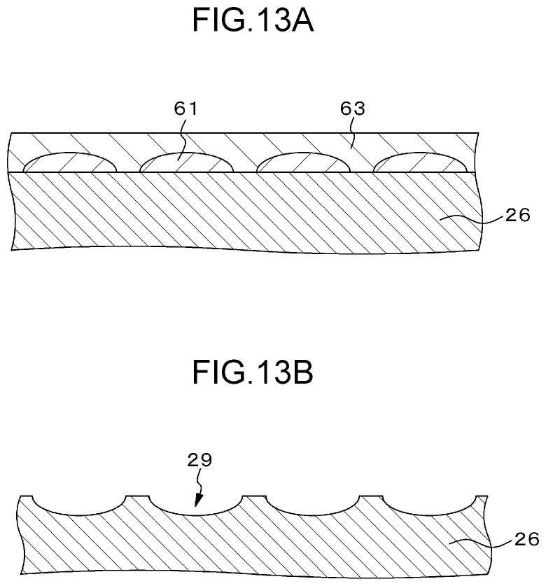

To form the recess 29 in the part of the base 26 where the light emitting element is to be formed, specifically, form a mask layer 61 made of SiN on the base 26 made of SiO₂, and form a resist layer 62 to which a shape for forming the recess is imparted on the mask layer 61 (see FIGS. 12A and 12B). Then, etch back the resist layer 62 and the mask layer 61 to transfer the shape formed on the resist layer 62 to the mask layer 61 (see FIG. 12C). Next, after the resist layer 63 is formed on the entire surface (see FIG. 13A), etch back the resist layer 63, the mask layer 61, and the base 26, whereby the recess 29 may be formed in the base 26 (see FIG. 13B). The recess 29 may be formed in the base 26 by appropriately selecting the material of the resist layer 63 and appropriately setting the etching conditions for etching back the resist layer 63, the mask layer 61, and the base 26, specifically, by selecting a material system and an etching condition with which the etching speed of the resist layer 63 is lower than the etching speed of the mask layer 61.

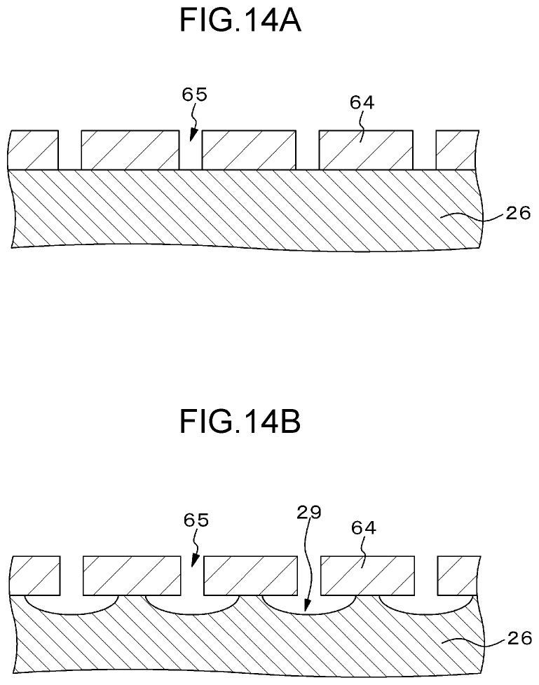

Alternatively, form a resist layer 64 having an opening 65 on the base 26 (see FIG. 14A). Then, perform wet etching on the base 26 via the opening 65, whereby the recess 29 may be formed in the base 26 (see FIG. 14B).

The second protective layer 34A may be formed on the entire surface based on, for example, an ALD method. The second protective layer 34A is formed on the second electrode 32 following the shape of the top surface of the second electrode 32 and has a constant thickness in the recess 29. Subsequently, after the protective layer 34 is formed on the entire surface based on a coating method, a planarization treatment may be performed on the top surface of the protective layer 34.

In this manner, in the light emitting element of Modification-5 of the display device of Example 1, a recess is provided on the surface of the base, and the first electrode, the organic layer, and the second electrode are formed substantially following the shape of the top surface of the recess. Since the recess is formed as described above, the recess can function as a kind of concave mirror. As a result, the front light extraction efficiency can further improve, the current-light emission efficiency remarkably improves, and the manufacturing process does not significantly increase. In addition, since the organic layer has a constant thickness, the resonator structure can be easily formed. Further, since the first electrode has a constant thickness, it is possible to reduce occurrence of a phenomenon such as coloring or luminance change of the first electrode depending on the angle at which the display device is viewed due to a thickness change of the first electrode.

Since the region other than the recess 29 is also composed of the stacked structure of the first electrode 32, the organic layer 33, and the second electrode 32, light is also emitted from this region. This may cause a decrease in light collection efficiency and a decrease in monochromaticity due to light leakage from adjacent pixels. Here, since the boundary between the insulating layer 28 and the first electrode 31 is an end of the light emitting area, the region where light is emitted may be optimized by optimizing this boundary.

In particular, in a microdisplay having a small pixel pitch, high front light extraction efficiency can be achieved even when an organic layer is formed in a recess with a reduced depth, which is suitable for application to future mobile applications. In the light emitting element of Modification-5 of the display device of Example 1, the current-light emission efficiency is further improved as compared with the conventional light emitting elements, and it is possible to realize long life and high luminance of the light emitting element and the display device. In addition, the light emitting element can be applied to a remarkably expanded range of eyewear, augmented reality (AR) glasses, and EVR.

The larger the depth of the recess is, the more light emitted from the organic layer and reflected by the first electrode can be collected in a direction toward the central part of the light emitting element. However, when the depth of the recess is large, it may be difficult to form the organic layer in the upper part of the recess. In this regard, since an internal lens is formed by the second protective layer and the protective layer, light reflected by the first electrode can be collected in a direction toward the central part of the light emitting element even when the depth of the recess is small, and the front light extraction efficiency can further improve. Moreover, since the internal lens is formed in a self-alignment manner with respect to the organic layer, there is no misalignment between the organic layer and the internal lens. In addition, since the angle of light passing through the color filter layer with respect to a base virtual plane can be increased by forming the recess and the internal lens, occurrence of color mixture between adjacent pixels can be effectively prevented. Thus, color gamut reduction caused by the optical color mixture between adjacent pixels is remedied, and the color gamut of the display device can improve. In general, the closer the organic layer and the lens are, the more efficiently light can be spread to a wide angle. However, since the distance between the internal lens and the organic layer is very short, the design width and the design freedom of the light emitting element are widened. Moreover, by appropriately selecting the thicknesses and materials of the protective layer and the second protective layer, the distance between the internal lens and the organic layer and the curvature of the internal lens can be changed, and the design width and design freedom of the light emitting element are further expanded. Further, since no heat treatment is required to form the internal lens, the organic layer is not damaged.

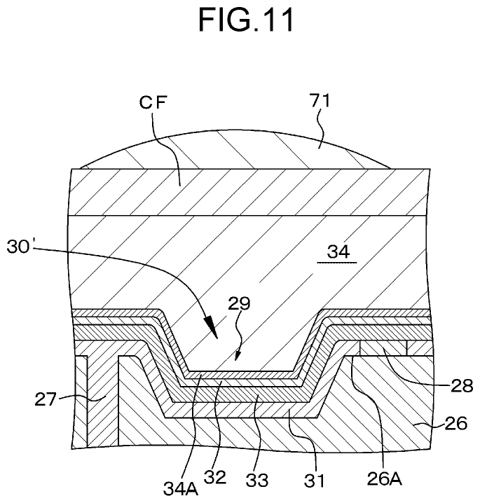

In the example illustrated in FIG. 9, the sectional shape of the recess 29 when the recess 29 is cut along the virtual plane including the axis AX of the recess 29 has a smooth curve. However, as illustrated in FIG. 11, the sectional shape may be formed into a part of a trapezoid. By forming the sectional shape of the recess 29 into these shapes, the inclination angle of the slope 29A can be increased. As a result, even when the depth of the recess 29 is small, extraction of light emitted from the organic layer 33 and reflected by the first electrode 31 can improve in the front direction.

The light emitting unit 30 may have a sectional shape protruding toward the first substrate 41 as described above or may have an uneven sectional shape toward the first substrate.

### Example 2

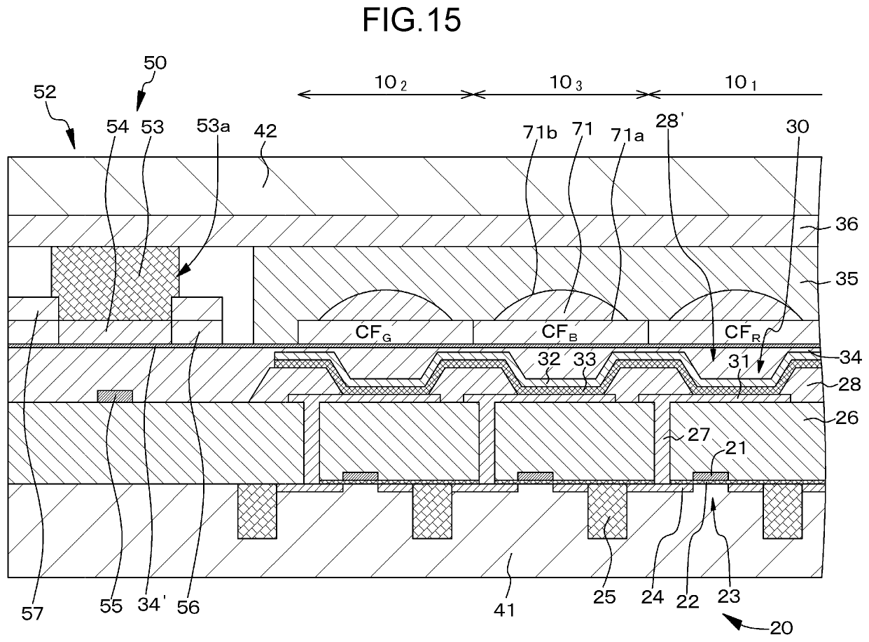

Example 2 is a modification of Example 1. As FIG. 15 illustrates a schematic and partial sectional view of the display device of Example 2 similar to a view taken along the arrow A-A in FIG. 3, the light emitting element 10 includes a planarization layer 34′ between the second electrode 32 and the color filter layer CF (specifically, between the protective layer 34 and the color filter layer CF), and the base material layer 54 includes a stacked structure of a material constituting the planarization layer 34′, specifically, a material constituting the planarization layer 34′ and a material constituting the optical path control unit 71. That is, the display device of Example 2 is a display device of configuration 2-B. In some cases, the base material layer 54 may be formed only of the material forming the planarization layer 34′. That is, the display device of Example 2 may be a display device of configuration 2-C.

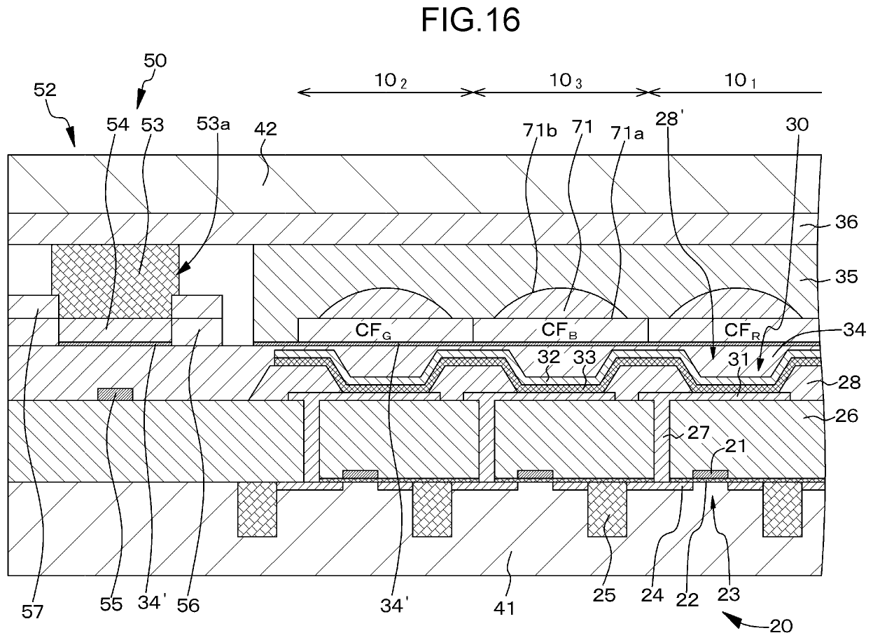

As FIG. 16 illustrates a schematic and partial sectional view of a modification of the display device of Example 2 similar to a view taken along the arrow A-A in FIG. 3, the planarization layer 34′ may be formed in a portion of the display region and a portion of the sub sealing part 52.

A schematic and partial sectional view of the display device of Example 2 or a modification thereof similar to a view taken along the arrow B-B in FIG. 3 is the same as FIG. 2.

### Example 3

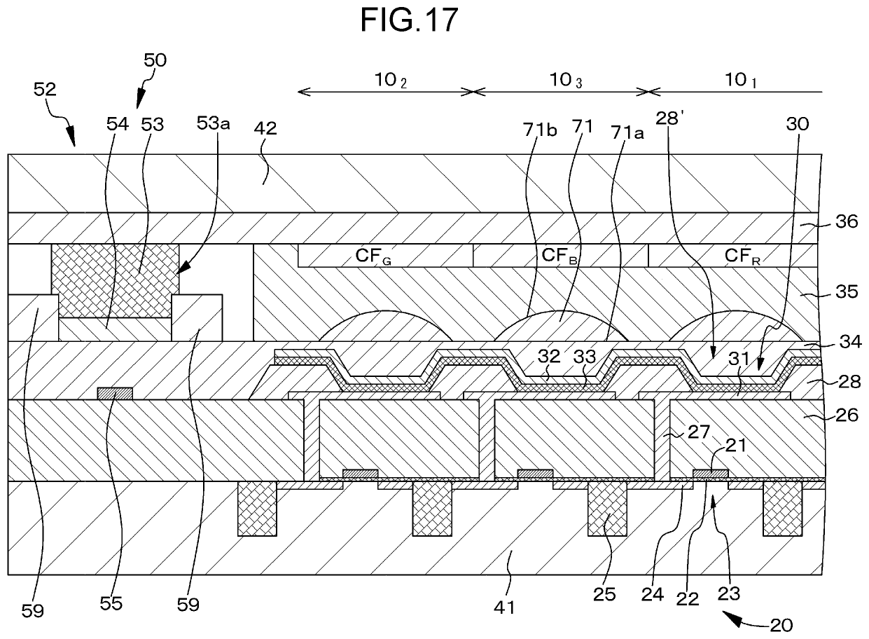

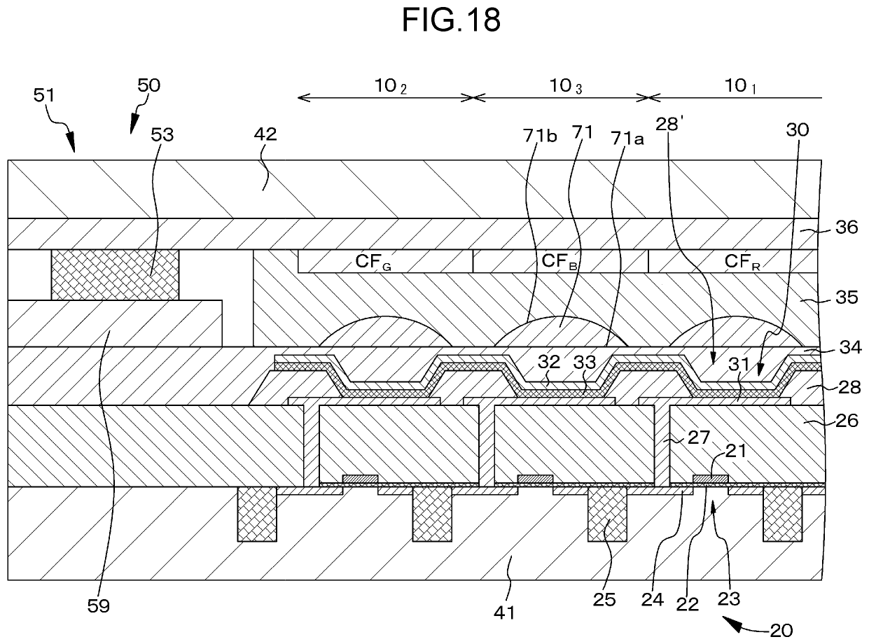

Example 3 is a modification of Examples 1 and 2. The optical path control unit 71 may be provided beneath or below the color filter layer CF. FIG. 17 is a schematic and partial sectional view of a display device of Example 3 similar to a view taken along the arrow A-A in FIG. 3. FIG. 18 is a schematic and partial sectional view of the display device of Example 3 similar to a view taken along the arrow B-B in FIG. 3. In the display device, the color filter layer is provided on the second substrate side.

Specifically, in the light emitting element of Example 3, the color filter layer CF is provided on or above the optical path control unit 71 (in the illustrated example, above the optical path control unit 71). More specifically, the optical path control unit 71 is provided on the protective layer 34, the underlayer 36 and the color filter layer CF are sequentially provided on the inner surface of the second substrate 42, and the optical path control unit 71, the protective layer 34, and the color filter layer CF are bonded to each other by the bonding member 35.

A light shielding member layer 59 is made of, for example, a thermosetting resin (e.g., an acrylic resin, an epoxy resin, a urethane resin, a silicone resin, or a cyanoacrylate resin) colored in black or the like, an ultraviolet curable resin, or a light photosensitive resin, in place of the light shielding member layer 56 (color filter layer CF_{R}) and the light shielding member layer 57 (color filter layer CF_{R}) in Examples 1 and 2. That is, the display device of Example 3 is a display device of configuration 1-B. The base material layer 54 is made of a material constituting the optical path control unit 71. The display device of Example 1 or a modification thereof and the display device of Example 2 or a modification thereof may also be a display device of configuration 1-B.

The configuration and structure of the display device of Example 3 may be the same as the configuration and structure of the display device described in Examples 1 and 2 except for the configuration and structure of the light shielding member layer 59 and the arrangement position of the color filter layer CF, and thus, detailed description is omitted.

### Example 4

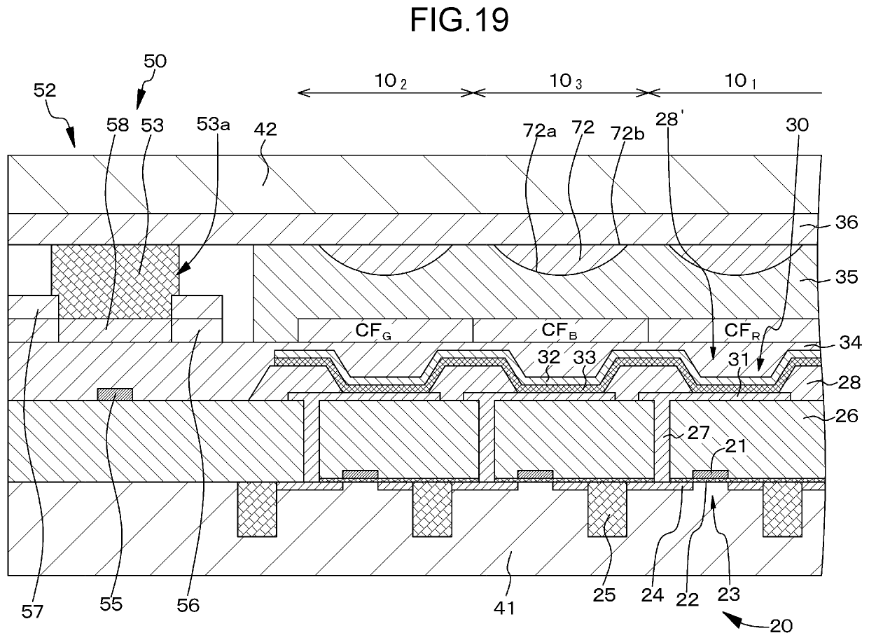

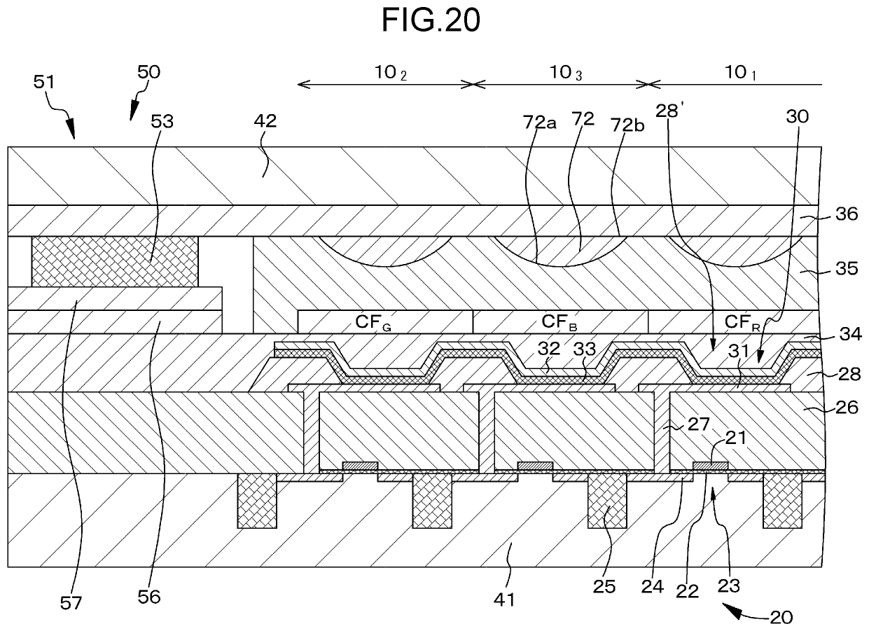

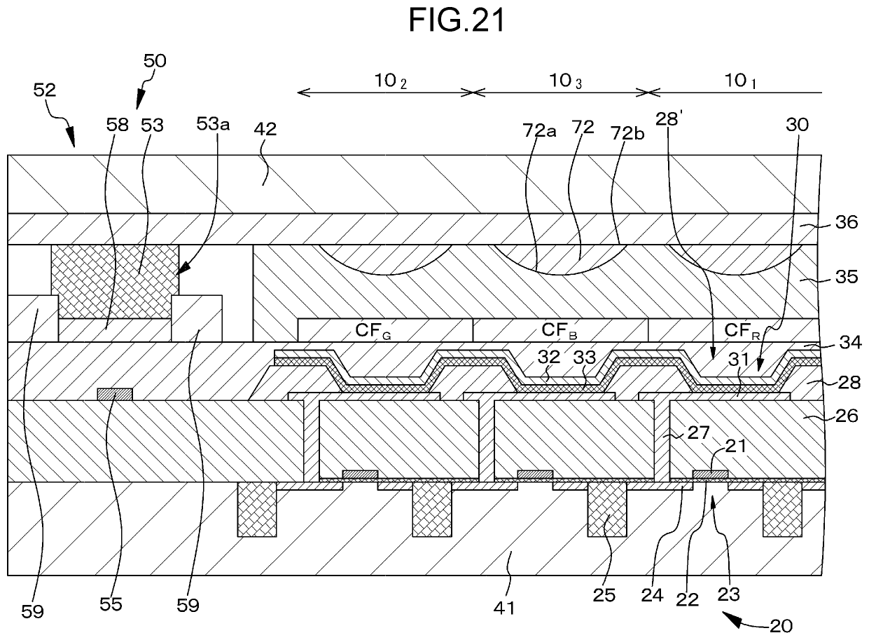

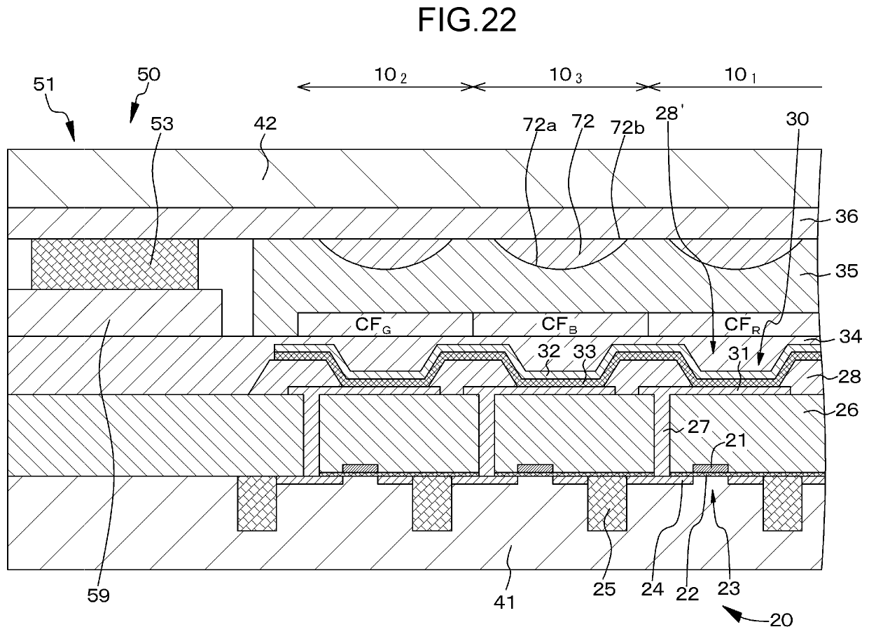

Example 4 is a modification of Examples 1 to 3. FIGS. 19 and 21 are schematic and partial sectional views of a display device of Example 4 similar to a view taken along the arrow A-A in FIG. 3. FIGS. 20 and 22 are schematic and partial sectional views of the display device of Example 4 similar to a view taken along the arrow B-B in FIG. 3.

In the display device of Example 4, an optical path control unit 72 is provided on the second substrate side. Since the color filter layer CF is provided on the first substrate side, the display device of configuration 1-A (see FIGS. 19 and 20) or the display device of configuration 1-B (see FIGS. 21 and 22) is adopted.

The optical path control unit 72 is formed of a plano-convex lens having a convex shape in a direction toward the second electrode 32. That is, a light emission surface 72a of the optical path control unit 72 has a convex shape, and a light incident surface 72b is flat, for example. The optical path control unit 72 is provided on the second substrate side. Thus, the base material layer 58 may be a material constituting the planarization layer 34′ (a display device of configuration 2-C). Alternatively, the base material layer 54 is made of a material other than the material constituting the planarization layer 34′ and the material constituting the optical path control unit 72, that is, in a broad sense, a material transparent to light (transparent material) for detecting the alignment mark 55, specifically, for example, a polyimide resin, an epoxy resin, an acrylic resin, a urethane resin, a polyester resin, or a polyolefin resin (display device of configuration 2-D).

The configuration and structure of the display device of Example 4 may be the same as the configuration and structure of the display device described in Examples 1 to 3 except for the configuration and structure of the base material layer 54 and the arrangement position of the optical path control unit 72, and thus, detailed description is omitted.

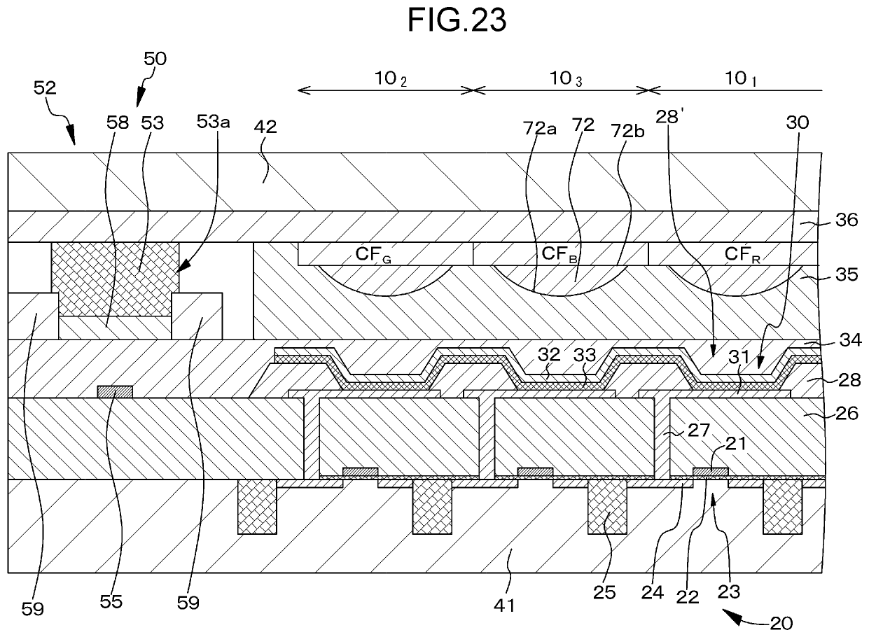

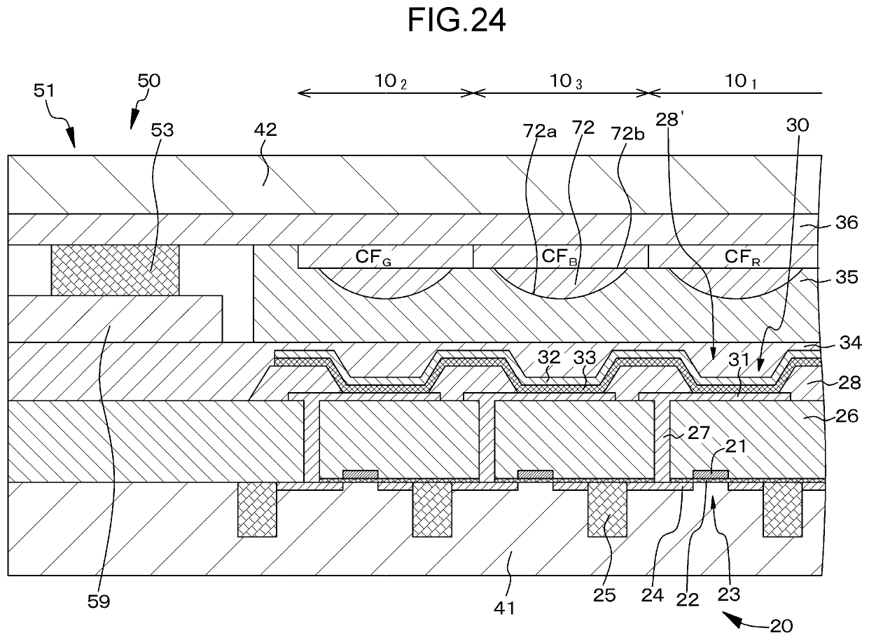

The color filter layer CF may be provided on the second substrate side as FIG. 23 illustrates a schematic and partial sectional view of Modification-1 of the display device of Example 4 similar to a view taken along the arrow A-A in FIG. 3 and as FIG. 24 illustrates a schematic and partial sectional view of Modification-1 of the display device of Example 4 similar to a view taken along the arrow B-B in FIG. 3. Specifically, the color filter layer CF may be provided between the second substrate 42 and the optical path control unit 72 (more specifically, between the underlayer 36 and the optical path control unit 72). In this Modification-1, the display device of configuration 1-B, the display device of configuration 2-C, or the display device of configuration 2-D may be adopted.

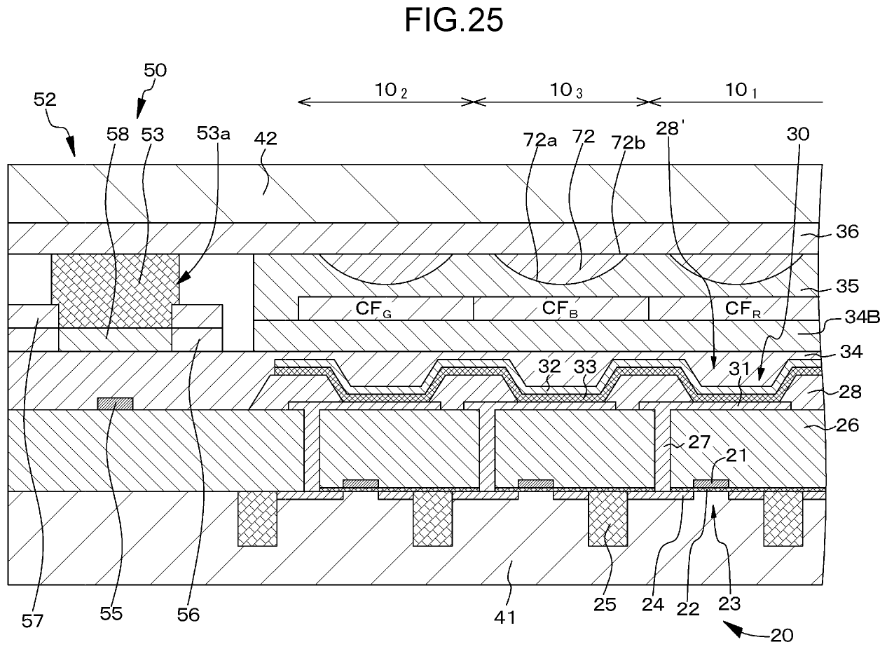

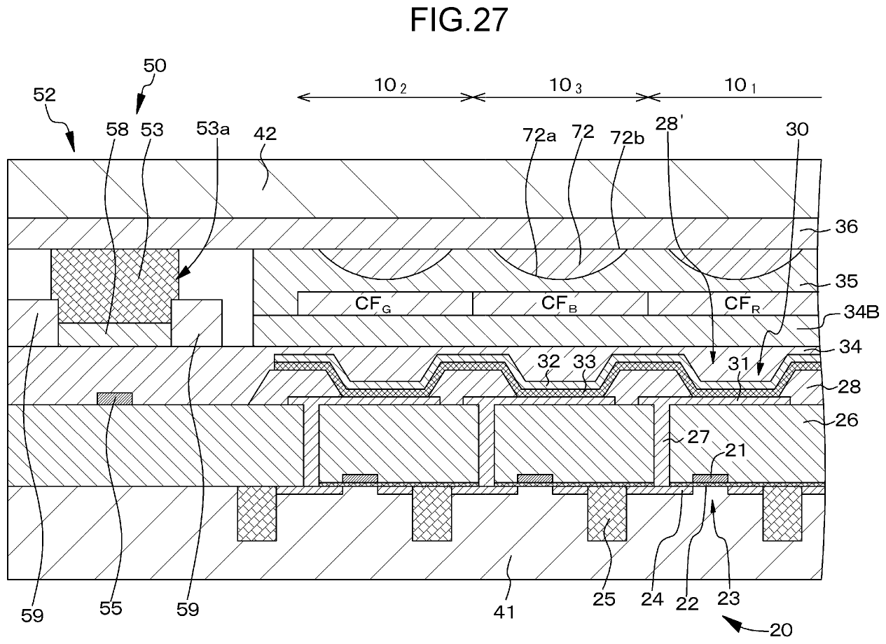

Alternatively, the color filter layer CF may be provided between the protective layer 34 and the optical path control unit 72 as FIGS. 25 and 27 illustrate schematic and partial sectional views of Modification-2 of the display device of Example 4 similar to a view taken along the arrow A-A in FIG. 3 and FIGS. 26 and 28 illustrate schematic and partial sectional views of Modification-2 of the display device of Example 4 similar to a view taken along the arrow B-B in FIG. 3. Specifically, a third protective layer 34B is formed on the protective layer 34, and the color filter layer CF is provided on the third protective layer 34B. That is, in this Modification-2, the display device of configuration 1-B, the display device of configuration 2-A, the display device of configuration 2-B, the display device of configuration 2-C, or the display device of configuration 2-D may be adopted. The color filter layer CF, the third protective layer 34B, and the optical path control unit 72 are bonded together by the bonding member 35.

The present disclosure has been described above based on preferred Examples. The present disclosure is not limited to these Examples. The configurations and structures of the display device (organic EL display device) and the light emitting element (organic EL element) described in Examples are examples and may be appropriately changed, and the production methods of the light emitting element and the display device are also examples and may be appropriately changed. The configuration and structure of the sealing part of the present disclosure can be applied to, for example, a liquid crystal display device.

The number of optical path control units for one pixel may essentially take any number, and the number is one or more. For example, when one pixel is composed of a plurality of subpixels, one optical path control unit may be provided corresponding to one subpixel, one optical path control unit may be provided corresponding to a plurality of subpixels, or a plurality of optical path control units may be provided corresponding to one subpixel. When p×q of optical path control units are provided corresponding to one subpixel, the values of p, q may be 10 or less, preferably 5 or less, more preferably 2 or less.

In Examples, one pixel is mostly composed of three subpixels with a combination of a white light emitting element and a color filter layer, but for example, one pixel may be composed of four subpixels including a light emitting element that emits white light. Alternatively, the light emitting elements may be a red light emitting element in which the organic layer generates red, a green light emitting element in which the organic layer generates green, and a blue light emitting element in which the organic layer generates blue, and one pixel may be composed of a combination of these three types of light emitting elements (subpixels). In Examples, the light emitting element drive unit (drive circuit) is composed of a MOSFET, but it may be composed of a TFT. The first electrode and the second electrode may have a single-layer structure or a multilayer structure. In some cases, the formation of the color filter layer may be omitted, and in such cases, the display device of configuration 1-B may be adopted.

A light shielding unit may be provided between light emitting elements to prevent light emitted from a light emitting unit constituting a certain light emitting element from entering a light emitting element adjacent to the certain light emitting element to cause optical crosstalk. That is, a groove may be formed between the light emitting elements, and the light shielding unit may be formed by embedding the groove with a light shielding material. With the light shielding unit provided in this manner, it is possible to reduce probability of entering of light emitted from a light emitting unit constituting a certain light emitting element into an adjacent light emitting element, and it is possible to reduce occurrence of a phenomenon in which color mixture occurs and chromaticity of the entire pixel deviates from desired chromaticity. Since color mixture can be prevented, the color purity when the pixel emits light in a single color is increased, and the chromaticity point is deepened. Thus, the color gamut is widened, and the range of color representation of the display device is widened. Specific examples of the light shielding material constituting the light shielding unit include materials capable of shielding light, such as titanium (Ti), chromium (Cr), tungsten (W), tantalum (Ta), aluminum (Al), and MoSi₂. The light shielding layer may be formed by vapor deposition methods including an electron beam vapor deposition method, a hot filament vapor deposition method, and a vacuum vapor deposition method, sputtering methods, CVD methods, ion plating methods, and the like. In addition, the color filter layer disposed for each pixel to improve the color purity may be thinned or omitted depending on the configuration of the light emitting element, which enables light absorbed in the color filter layer to be extracted, resulting in an improvement in the light emission efficiency. Alternatively, a light shielding property may be imparted to the black matrix layer BM.

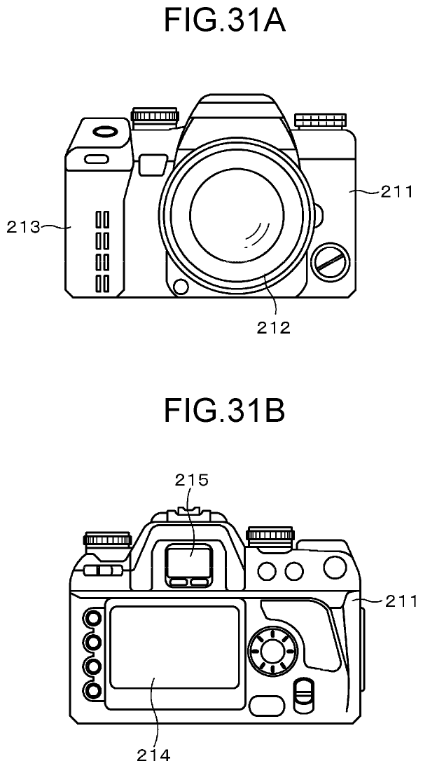

The display device of the present disclosure may be applied to a mirrorless interchangeable lens digital still camera. FIG. 31A is a front view of a digital still camera. FIG. 31B is a back view of the digital still camera. This mirrorless interchangeable lens digital still camera includes, for example, an interchangeable imaging lens unit (interchangeable lens) 212 on the front right side of a camera body 211, and a grip 213 to be held by a photographer on the front left side. A monitor device 214 is provided substantially at the center of the back surface of the camera body 211. An electronic view finder (eyepiece window) 215 is provided above the monitor device 214. The photographer can visually recognize an optical image of a subject guided from the imaging lens unit 212 and determine a composition by looking into the electronic view finder 215. The display device of the present disclosure can be used as the electronic view finder 215 in a mirrorless interchangeable lens digital still camera having such a configuration.

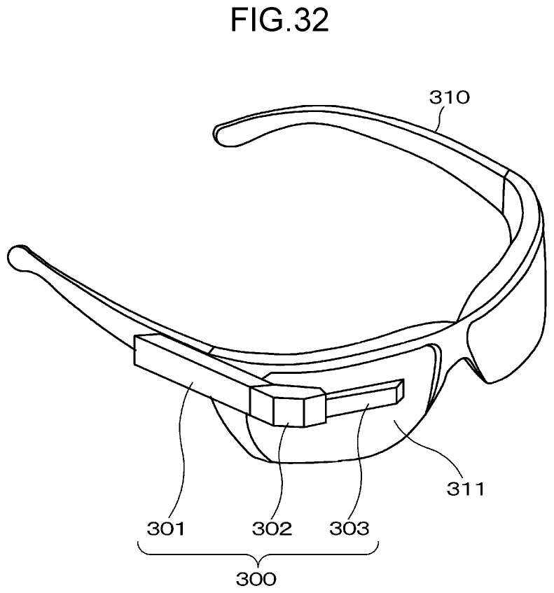

The display device of the present disclosure may also be applied to a head mounted display. As illustrated in the external view of FIG. 32, a head mounted display 300 is composed of a transmissive head mounted display including a main body 301, an arm 302, and a lens barrel 303. The main body 301 is connected to the arm 302 and eyeglasses 310. Specifically, an end of the main body 301 in a long side direction is attached to the arm 302. One side surface of the main body 301 is connected to the eyeglasses 310 via a connection member (not illustrated). The main body 301 may be directly mounted on the head of a human body. The main body 301 incorporates a control board and a display unit for controlling the operation of the head mounted display 300. The arm 302 connects the main body 301 and the lens barrel 303 to support the lens barrel 303 with respect to the main body 301. Specifically, the arm 302 is coupled to an end of the main body 301 and an end of the lens barrel 303 to fix the lens barrel 303 to the main body 301. The arm 302 incorporates a signal line for communicating data related to an image provided from the main body 301 to the lens barrel 303. The lens barrel 303 projects image light provided from the main body 301 via the arm 302 toward the eyes of a user wearing the head mounted display 300 through a lens 311 of the eyeglasses 310. The display device of the present disclosure can be used as the display unit incorporated in the main body 301 in the head mounted display 300 having the above configuration.

As an alternative to the color filter layer described above, a wavelength selection unit may be adopted. Examples of the wavelength selection unit include a photonic crystal, a wavelength selection element to which plasmon is applied (for example, a wavelength selection unit having a conductor grid structure in which a grid-shaped hole structure is provided in a conductor thin film disclosed in JP 2008-177191 A, or a wavelength selection unit based on surface plasmon excitation using a diffraction grating), a wavelength selection unit with a dielectric multilayer film capable of transmitting a specific wavelength by using multiple reflection in a thin film formed by stacking dielectric thin films, a thin film made of an inorganic material such as thin film amorphous silicon, and a quantum dot. In these cases, the display device of configuration 1-B may be formed.

A relationship between the color filter layer or the like and the optical path control unit may take:
(a) a form in which an orthographic projection image of the optical path control unit matches with an orthographic projection image of the color filter layer or the like;
(b) a form in which the orthographic projection image of the optical path control unit is included in the orthographic projection image of the color filter layer; or
(c) a form in which the orthogonal projection image of the color filter layer or the like is included in the orthogonal projection image of the optical path control unit.

That is, the planar shape of the color filter layer or the like may be the same as, similar to, approximate to, or different from the planar shape of the optical path control unit. Adopting a form in which the orthogonal projection image of the optical path control unit is included in the orthogonal projection image of the color filter layer or the like can reliably reduce occurrence of color mixture between adjacent light emitting elements 10.

That is, the planar shape of the color filter layer or the like may be the same as, similar to, approximate to, or different from the planar shape of the optical path control unit. Adopting a form in which the orthogonal projection image of the optical path control unit is included in the orthogonal projection image of the color filter layer or the like can reliably reduce occurrence of color mixture between adjacent light emitting elements 10.

The planar shape of the color filter layer or the like may be the same as, similar to, approximate to, or different from the planar shape of the light emitting region, but the color filter layer is preferably larger than the light emitting region. The center of the color filter layer (the center when the color filter layer is orthogonally projected onto the first substrate) may pass through the center of the light emitting region but does not have to pass through the center of the light emitting region. The size of the color filter layer or the like may be appropriately changed according to the distance (offset amount) do between the normal line passing through the center of the light emitting region and the normal line passing through the center of the color filter layer or the like. The various normal lines are perpendicular to the first substrate.

The center of the color filter layer or the like refers to an area centroid point of a region occupied by the color filter layer or the like. Alternatively, when the planar shape of the color filter layer or the like is a circle, an ellipse, a square (including a square with rounded corners), a rectangle (including a rectangle with rounded corners), or a regular polygon (including a regular polygon with rounded corners), the center of these shapes corresponds to the center of the color filter layer or the like. When the planar shape has a shape in which a part of these shapes is cutout, the center of the shape complementing the cutout part corresponds to the center of the color filter layer or the like. When the planar shape has a shape in which these shapes are connected, the connection part is removed, and the center of the shape complementing the removed part corresponds to the center of the color filter layer or the like. The center of the optical path control unit refers to an area centroid point of a region occupied by the optical path control unit. When the planar shape of the optical path control unit is a circle, an ellipse, a square (including a square with rounded corners), a rectangle (including a rectangle with rounded corners), or a regular polygon (including a regular polygon with rounded corners), the center of these shapes corresponds to the center of the optical path control unit. The center of the light emitting region refers to an area centroid point of a region where the first electrode and the organic layer are in contact with each other.

The size of the planar shape of the optical path control unit may be changed depending on the light emitting element 10. For example, when one light emitting element 10 unit (pixel) is composed of three light emitting elements 10 (subpixels), the sizes of the planar shape of the optical path control units may have the same value in the three light emitting elements 10 that forms one light emitting element 10 unit, may have the same value in the two light emitting elements 10 except for one light emitting element 10, or may have different values in the three light emitting elements 10. The refractive index of the material constituting the optical path control unit may be changed depending on the light emitting element 10. For example, when one light emitting element 10 unit (pixel) is composed of three light emitting elements 10 (subpixels), the refractive indexes of the materials constituting the optical path control units may have the same value in the three light emitting elements 10, may have the same value in the two light emitting elements 10 except for one light emitting element 10, or may have different values in the three light emitting elements 10.

The lens member constituting the optical path control unit may be formed in a hemispherical shape or a part of a sphere, or may be formed in a shape suitable for functioning as a lens in a broad sense. Specifically, as described above, the lens member may be composed of a convex lens member, specifically, a plano-convex lens. The lens member may be a spherical lens or an aspherical lens. The optical path control unit may be a refractive lens or a diffractive lens.

The optical path control unit may be a lens member having, as a whole, a rounded three-dimensional shape of a rectangular parallelepiped having a square or rectangular bottom surface, in which the four side surfaces and one top surface of the rectangular parallelepiped have convex shapes, ridge parts where the side surfaces intersect each other are rounded, and ridge parts where the top surface intersects the side surfaces are also rounded. The optical path control units may be a lens member having a three-dimensional shape of a rectangular parallelepiped (including a cube approximating a rectangular parallelepiped) having a square or rectangular bottom surface, in which the four side surfaces and one top surface of the rectangular parallelepiped have a planar shape. In this case, ridge parts where the side surfaces intersect each other may be rounded in some case, and ridge parts where the top surface intersects the side surfaces may also be rounded in some cases. The lens member may be composed of a lens member having a rectangular or isosceles trapezoidal sectional shape cut along a virtual plane (vertical virtual plane) including its thickness direction. In other words, the lens member may be composed of a lens member whose sectional shape is constant or changed along the thickness direction.

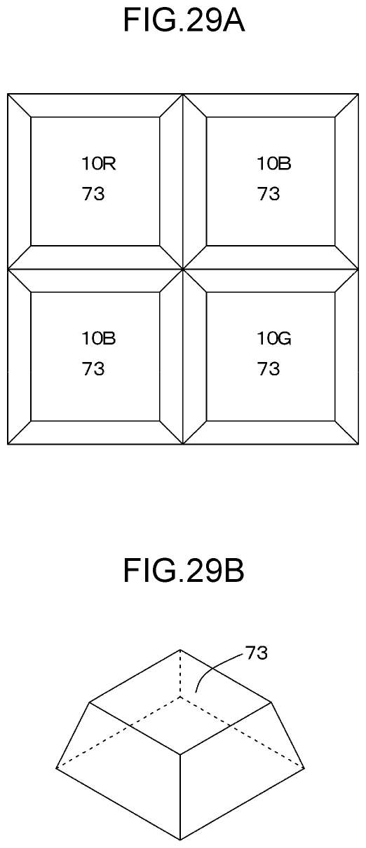

That is, in Examples, the planar shape of the optical path control unit 71 is a circle shape, but the shape is not limited to a circle shape. As illustrated in FIGS. 29A and 29B, the lens member may be a truncated quadrangular pyramid. FIG. 29A is a schematic plan view of an optical path control unit (lens member) 73 having a truncated quadrangular pyramid shape, and FIG. 29B is a schematic perspective view thereof.

Alternatively, the optical path control unit may be composed of a light emission direction control member having a rectangular or isosceles trapezoidal sectional shape cut along a virtual plane (vertical virtual plane) including its thickness direction. In other words, the optical path control unit may be composed of a light emission direction control member whose sectional shape is constant or changed along the thickness direction.

To increase the light use efficiency of the entire display device, it is preferable to effectively collect light at the outer edge of the light emitting element. However, in a hemispherical lens, although the effect of collecting light near the center of the light emitting element to the front is large, the effect of collecting light near the outer edge of the light emitting element may be small.

The side surfaces of the light emission direction control member constituting the optical path control unit are surrounded by a material or layer (covering layer) having a refractive index lower than the refractive index of the material constituting the light emission direction control member. Thus, the light emission direction control member has a function as a kind of lens, and it can effectively enhance the light collection effect in the vicinity of the outer edge of the light emission direction control member. In geometrical optics, when a light beam is incident on a side surface of the light emission direction control member, the incident angle and the reflection angle is equal, and thus it is difficult to improve the extraction of light in the front direction. However, in wave motion analysis (FDTD), the light extraction efficiency in the vicinity of the outer edge of the light emission direction control member improves. Thus, light in the vicinity of the outer edge of the light emitting element can be effectively collected, and as a result, the light extraction efficiency in the front direction of the entire light emitting element can improve. This can achieve high light emission efficiency of the display device. That is, it is possible to realize high luminance and low power consumption of the display device. The light emission direction control member, which has a flat plate shape, can be formed easily, and the production process can be simplified.

Specifically, examples of the three-dimensional shape of the light emission direction control member include a columnar shape, an elliptical columnar shape, an oval columnar shape, a cylindrical shape, a prismatic shape (including a hexagonal prism, an octagonal prism, and a prism with rounded ridges), a truncated conical shape, and a truncated pyramidal shape (including a truncated pyramidal shape with rounded ridges). The prism shape and the truncated pyramid shape include a regular prism shape and a regular truncated pyramid shape. The ridge part where a side surface of the light emission direction control member intersects the top surface may be rounded. The bottom surface of the truncated pyramid may be positioned on the first substrate side or on the second electrode side. Specific examples of the planar shape of the light emission direction control member include a circle, an ellipse, an oval, and a polygon including a triangle, a quadrangle, a hexagon, and an octagon. The polygon includes a regular polygon (including a regular polygon such as a rectangle or a regular hexagon (honeycomb shape)). The light emission direction control member may be made of, for example, a transparent resin material, such as an acrylic resin, an epoxy resin, a polycarbonate resin, or a polyimide resin, or a transparent inorganic material, such as SiO₂.

The sectional shape of the side surfaces of the light emission direction control member in the thickness direction may be linear, convexly curved, or concavely curved. That is, the side surfaces of the prism or the truncated pyramid may be flat, convexly curved, or concavely curved.

A light emission direction control member extending unit having a thickness smaller than that of the light emission direction control member may be formed between the light emission direction control member and the light emission direction control member adjacent to each other.

The top surface of the light emission direction control member may be flat, may have an upward convex shape, or may have an upward concave shape, but from the viewpoint of improving the luminance in the front direction of the image display region (display panel) of the display device, the top surface of the light emission direction control member is preferably flat. The light emission direction control member may be obtained by, for example, a combination of a photolithography technique and an etching method or may be formed based on a nanoimprint method.

The size of the planar shape of the light emission direction control member may be changed depending on the light emitting element. For example, when one pixel is composed of three subpixels, the size of the planar shape of the light emission direction control member may have the same value in the three subpixels constituting one pixel, may have the same value in two subpixels except for one subpixel, or may have different values in the three subpixels. The refractive index of the material constituting the light emission direction control member may also be changed depending on the light emitting element. For example, when one pixel is composed of three subpixels, the refractive index of the material constituting the light emission direction control member may have the same value in the three subpixels constituting one pixel, may have the same value in two subpixels except for one subpixel, or may have different values in the three subpixels.

The planar shape of the light emission direction control member is preferably similar or approximate to the light emitting region, or the light emitting region is preferably included in an orthogonal projection image of the light emission direction control member.

The side surfaces of the light emission direction control member are preferably vertical or substantially vertical. Specifically, examples of the inclination angle of the side surfaces of the light emission direction control member may include 80 degrees to 100 degrees, preferably 81.8 degrees or more and 98.2 degrees or less, more preferably 84.0 degrees or more and 96.0 degrees or less, still more preferably 86.0 degrees or more and 94.0 degrees or less, particularly preferably 88.0 degrees or more and 92.0 degrees or less, and most preferably 90 degrees.

Examples of the average height of the light emission direction control member may include 1.5 μm or more and 2.5 μm or less, with which the light collection effect in the vicinity of the outer edge of the light emission direction control member can be effectively enhanced. The height of the light emission direction control member may be changed depending on the light emitting element. For example, when one pixel is composed of three subpixels, the height of the light emission direction control member may have the same value in the three subpixels constituting one pixel, may have the same value in two subpixels except for one subpixel, or may have different values in the three subpixels.

The shortest distance between the side surfaces of adjacent light emission direction control members may be 0.4 μm or more and 1.2 μm or less, preferably 0.6 μm or more and 1.2 μm or less, more preferably 0.8 μm or more and 1.2 μm or less, and still more preferably 0.8 μm or more and 1.0 μm or less. By defining the minimum value of the shortest distance between the side surfaces of adjacent light emission direction control members to be 0.4 μm, the shortest distance between the adjacent light emission direction control members can be set to be about the same as the lower limit value of the wavelength band of visible light, and thus, it is possible to reduce the functional degradation of the material or layer surrounding the light emission direction control member, and as a result, it is possible to effectively enhance the light collection effect in the vicinity of the outer edge of the light emission direction control member. On the other hand, by defining the maximum value of the shortest distance between the side surfaces of adjacent light emission direction control members as 1.2 μm, the size of the light emission direction control members can be reduced, and as a result, the light collection effect in the vicinity of the outer edge of the light emission direction control member can be effectively enhanced.

The distance between the centers of adjacent light emission direction control members is preferably 1 μm or more and 10 μm or less. With the distance set to 10 μm or less, the wave property of light remarkably appears, and thus a high light collection effect can be imparted to the light emission direction control members.

The maximum distance (maximum distance in a height direction) from the light emitting region to the bottom surface of the light emission direction control member is desirably more than 0.35 μm and 7 μm or less, preferably 1.3 μm or more and 7 μm or less, more preferably 2.8 μm or more and 7 μm or less, and still more preferably 3.8 μm or more and 7 μm or less. By defining the maximum distance from the light emitting region to the light emission direction control member to be more than 0.35 μm, the light collection effect in the vicinity of the outer edge of the light emission direction control member can be effectively enhanced. On the other hand, by defining the maximum distance from the light emitting region to the light emission direction control member to be 7 μm or less, deterioration of the viewing angle characteristics can be reduced.

The number of light emission direction control members for one pixel can essentially take any number, and the number is one or more. For example, when one pixel is composed of a plurality of subpixels, one light emission direction control member may be provided corresponding to one subpixel, one light emission direction control member may be provided corresponding to a plurality of subpixels, or a plurality of light emission direction control members may be provided corresponding to one subpixel. When p×q of light emission direction control members are provided corresponding to one subpixel, the values of p, q may be 10 or less, preferably 5 or less, and more preferably 2 or less.

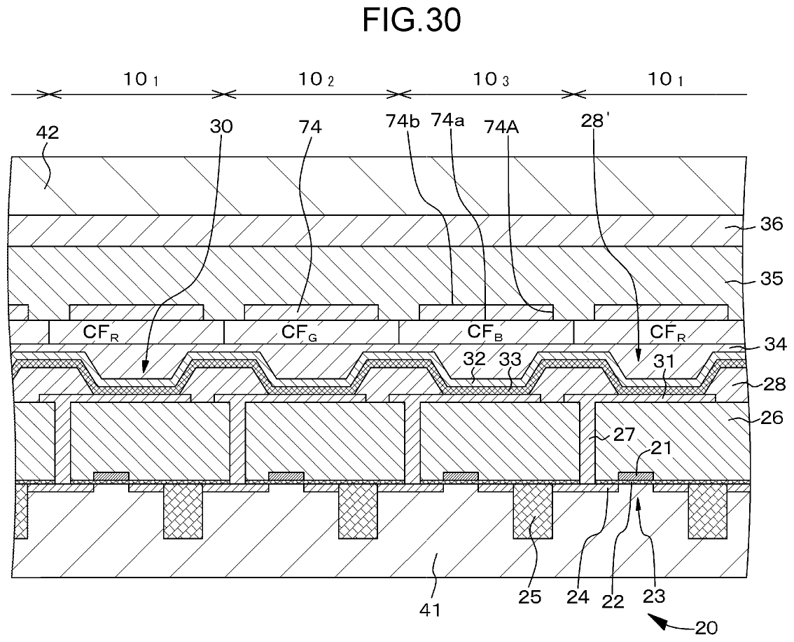

As illustrated in the schematic and partial sectional view in FIG. 30, a light emission direction control member 74 as an optical path control unit is provided above the light emitting units 30, 30′, specifically, at the same position as the optical path control units 71, 72. When the light emission direction control member is cut along a virtual plane (vertical virtual plane) including a thickness direction of the light emission direction control member 74, the sectional shape of the light emission direction control member 74 is rectangular. The three-dimensional shape of the light emission direction control member 74 is, for example, columnar. In the example illustrated in FIG. 30, since the light emission direction control member 74 is surrounded by the bonding member 35, the light emission direction control member 74 has a function as a kind of lens, and the light collection effect in the vicinity of the outer edge of the light emission direction control member 74 can be effectively enhanced, assuming that the refractive index of the material constituting the light emission direction control member 74 is n₁′ and the refractive index of the material constituting the bonding member 35 is n₂′ (n₂′<n₂′). In addition, the light emission direction control member 74, which has a flat plate shape, can be formed easily, and the production process can be simplified. The light emission direction control member 74 may be surrounded by a material different from the material constituting the bonding member 35 as long as the refractive index condition (n₂′<n₂′) is satisfied. Alternatively, the light emission direction control member 74 may be surrounded by, for example, an air layer or a decompression layer (vacuum layer). A light incident surface 74a and a light emission surface 74b of the light emission direction control member 74 are flat. Reference numerals 74A indicates a side surface of the light emission direction control member 74. The light emission direction control member 74 can be applied to various Examples and modifications thereof. In such case, the refractive index of the material surrounding the light emission direction control member 74 may be appropriately selected.

The light emitting element constituting the display device of Examples may have a resonator structure. That is, the organic EL display device preferably has a resonator structure to further improve the light extraction efficiency. When the resonator structure is provided, as described above, the resonator structure may be a resonator structure in which the organic layer 33 serves as a resonance part and is sandwiched between the first electrode 31 and the second electrode 32. Alternatively, as described below, the resonator structure may be formed by forming the light reflection layer 37 below the first electrode 31 (on the first substrate side), forming an interlayer insulating material layer 38 between the first electrode 31 and the light reflection layer 37, and having the organic layer 33 and the interlayer insulating material layer 38 as a resonance unit sandwiched between the light reflection layer 37 and the second electrode 32.

Specifically, light emitted from the light emitting layer included in the organic layer is caused to resonate between a first interface formed of an interface between the first electrode and the organic layer (or a first interface formed of an interface between the light reflection layer and the interlayer insulating material layer in a structure in which an interlayer insulating material layer is provided beneath the first electrode and a light reflection layer is provided beneath the interlayer insulating material layer as described below) and a second interface formed of an interface between the second electrode and the organic layer, and part of the light is emitted from the second electrode. The following Formulas (1-1) and (1-2) may be satisfied where the optical distance from the maximum light emission position of the light emitting layer to the first interface is OL₁, the optical distance from the maximum light emission position of the light emitting layer to the second interface is OL₂, and m₁ and m₂ are integers.

0.7{−Φ₁/(2π)+m₁}≤2×OL₁/λ≤1.2{−Φ₁/(2π)+m₁} (1-1)

0.7{−Φ₂/(2π)+m₂}≤2×OL₂/λ≤1.2{−Φ₂/(2π)+m₂} (1-2)
where
λ: a maximum peak wavelength of spectrum of light generated in the light emitting layer (or a desired wavelength of light generated in the light emitting layer)
Φ₁: a phase shift amount (unit: radian) of light reflected at the first interface where −2π<Φ₁≤0
Φ₂: a phase shift amount (unit: radian) of light reflected at the second interface where −2π<Φ₂≤0.

The value of m₁ is a value of 0 or more, and the value of m₂ is a value of 0 or more independently of the value of m₁. Examples thereof include (m₁, m₂)=(0, 0), (m₁, m₂)=(0, 1), (m₁, m₂)=(1, 0), and (m₁, m₂)=(1, 1).

The distance SD₁ from the maximum light emission position of the light emitting layer to the first interface refers to an actual distance (physical distance) from the maximum light emission position of the light emitting layer to the first interface. The distance SD₂ from the maximum light emission position of the light emitting layer to the second interface refers to an actual distance (physical distance) from the maximum light emission position of the light emitting layer to the second interface. The optical distance is also referred to as an optical path length, and it typically refers to n×SD when a light beam passes through a medium having a refractive index n by a distance SD. The same applies hereinafter. Thus,

OL₁=SD₁×nₐᵥₑ

OL₂=SD₂×nₐᵥₑ

are satisfied where nₐᵥₑ is an average refractive index. Here, the average refractive index nₐᵥₑ is obtained by summing up the product of the refractive index and the thickness of each layer constituting the organic layer (or, the organic layer, the first electrode, and the interlayer insulating material layer) and dividing the sum by the thickness of the organic layer (or, the organic layer, the first electrode, and the interlayer insulating material layer).

The light emitting element may be designed by determining a desired wavelength k (specifically, a red wavelength, a green wavelength, or a blue wavelength, for example) in light generated in the light emitting layer and obtaining various parameters such as OL₁ and OL₂ in the light emitting element based on Formulas (1-1) and (1-2).

The first electrode or the light reflection layer and the second electrode absorb part of incident light and reflect the rest. Thus, a phase shift occurs in the reflected light. The phase shift amounts Φ₁ and Φ₂ may be obtained by measuring the values of the real number part and the imaginary number part of the complex refractive index of the materials constituting the first electrode or the light reflection layer and the second electrode using, for example, an ellipsometer, and performing calculation based on these values (see, for example, “Principles of Optic”, Max Born and Emil Wolf, 1974 (PERGAMON PRESS)). The refractive index of the organic layer, the interlayer insulating material layer, or the like, the refractive index of the first electrode, or the refractive index of the first electrode in a case where the first electrode absorbs part of incident light and reflect the rest may also be determined by a measurement using an ellipsometer.

Examples of the material constituting the light reflection layer include aluminum, an aluminum alloy (for example, Al—Nd or Al—Cu), an Al/Ti stacked structure, an Al—Cu/Ti stacked structure, chromium (Cr), silver (Ag), a silver alloy (for example, Ag—Cu, Ag—Pd—Cu, or Ag—Sm—Cu), copper, a copper alloy, gold, and a gold alloy. The light reflection layer may be formed by, for example: vapor deposition methods including an electron beam vapor deposition method, a hot filament vapor deposition method, and a vacuum vapor deposition method; sputtering methods; CVD methods; ion plating methods; plating methods, such as electroplating methods and electroless plating methods; lift-off methods; laser ablation methods; and sol-gel methods. Depending on the material constituting the light reflection layer, it is preferable to form an underlayer made of, for example, TiN, to control the crystalline state of the light reflection layer to be formed.

In this manner, in the organic EL display device having a resonator structure, in practice, the light emitting unit constituting a red light emitting element causes light emitted from the organic layer to resonate, and emits reddish light (light having a light spectrum peak in a red region) from the second electrode. The light emitting unit constituting a green light emitting element causes light emitted from the organic layer to resonate, and emits greenish light (light having a light spectrum peak in a green region) from the second electrode. The light emitting unit constituting a blue light emitting element causes light emitted from the organic layer to resonate, and emits bluish light (light having a light spectrum peak in a blue region) from the second electrode. That is, each light emitting element may be designed by determining a desired wavelength k (specifically, a red wavelength, a green wavelength, or a blue wavelength) in light generated in the light emitting layer and obtaining various parameters such as OL₁ and OL₂ in each of the red light emitting element, green light emitting element, and the blue light emitting element based on Formulas (1-1) and (1-2). For example, paragraph [0041] of JP 2012-216495 A discloses an organic EL element having a resonator structure in which an organic layer serves as a resonance unit, and it describes that a film thickness of the organic layer is preferably 80 nm or more and 500 nm or less, and more preferably 150 nm or more and 350 nm or less because a distance from a light emitting point (light emitting surface) to a reflection surface can be appropriately adjusted. Usually, the value of (SD₁+SD₂=SD₁₂) is different in the red light emitting element, the green light emitting element, and the blue light emitting element.

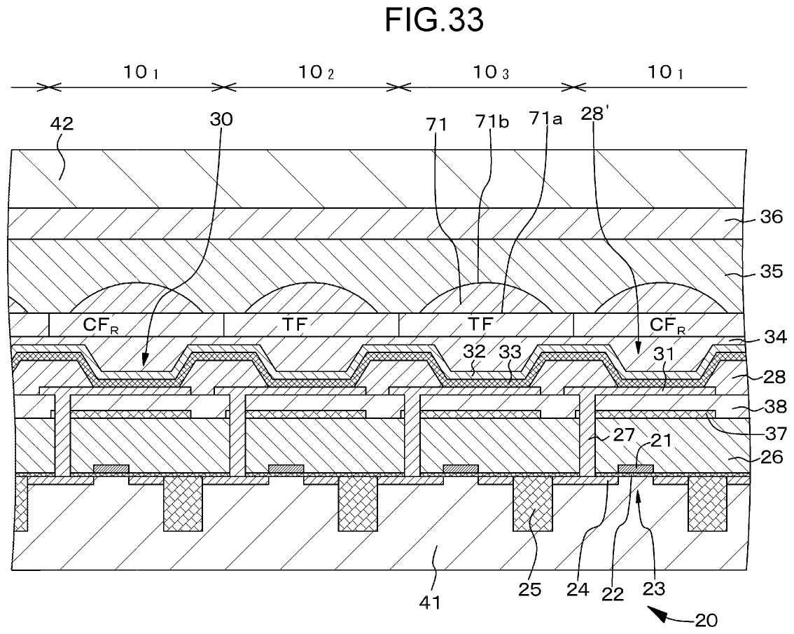

FIG. 33 is a schematic and partial sectional view of the display device, in which
each of the light emitting elements 10 has a resonator structure,
the first light emitting element 10₁ emits red light, the second light emitting element 10₂ emits green light, and the third light emitting element 10₃ emits blue light,
the first light emitting element 10₁ is provided with a color filter layer or the like that transmits the emitted red light, and
the second light emitting element 10₂ and the third light emitting element 10₃ are not provided with the color filter layer or the like.

Alternatively, the display device includes:
a first substrate 41 and a second substrate 42; and
a plurality of light emitting element units each including a first light emitting element 10₁, a second light emitting element 10₂, and a third light emitting element 10₃ provided on the first substrate 41,
wherein
each of the light emitting elements 10 includes light emitting units 30, 30′ provided above the first substrate 41,
each of the light emitting elements 10 has a resonator structure,
the first light emitting element 10₁ emits red light, the second light emitting element 10₂ emits green light, and the third light emitting element 10₃ emits blue light,
the first light emitting element 10₁ is provided with a color filter layer or the like that transmits emitted red light, and
the second light emitting element 10₂ and the third light emitting element 10₃ are not provided with the color filter layer or the like.

Here, the red color filter layer CF_{R} is given as the color filter layer or the like that transmits the emitted red light, but the color filter layer or the like is not limited to the red color filter layer CF_{R}. In the second light emitting element 10₂ and the third light emitting element 10₃, a transparent filter layer TF is provided instead of the color filter layer.

Optimum OL₁ and OL₂ may be obtained in each of the first light emitting element 10₁ to display red, the second light emitting element 10₂ to display green, and the third light emitting element 10₃ to display blue based on the above-described Formulas (1-1) and (1-2), whereby an emission spectrum having a sharp peak can be obtained in each light emitting element. The first light emitting element 10₁, the second light emitting element 10₂, and the third light emitting element 10₃ have the same configuration and structure except for the color filter layer CF_{R}, the filter layer TF, and the resonator structure (configuration of the light emitting layer).

In some cases, in addition to the maximum peak wavelength λ_{R} (red) of the spectrum of light generated in the light emitting layer provided in the first light emitting element 10₁ to display red, light having a wavelength λ_{R}′ shorter than λ_{R} resonates in the resonator, depending on the settings of m₁ and m₂. Similarly, in addition to the maximum peak wavelength λ_{G} (green) of the spectrum of light generated in the light emitting layer provided in the second light emitting element 10₂ to display green, light having a wavelength λ_{G}′ shorter than λ_{G} resonates in the resonator in some cases. In addition to the maximum peak wavelength λ_{B} (blue) of the spectrum of light generated in the light emitting layer provided in the third light emitting element 10₃ to display blue, light having a wavelength λ_{B}′ shorter than λ_{B} resonates in the resonator in some cases. Usually, light having wavelengths λ_{G}′, λ_{B}′ is out of the range of visible light, and thus it is not observed by an observer of the display device. However, light having a wavelength λ_{R}′ may be observed as blue by an observer of the display device.

Thus, in such a case, there is n₀ need to provide the color filter layer or the like in the second light emitting element 10₂ or the third light emitting element 10₃, but it is preferable to provide the color filter layer or the like that transmits the emitted red light in the first light emitting element 10₁. With this configuration, it is possible to display an image with high color purity with the first light emitting element 10₁, and it is possible to achieve high light emission efficiency in the second light emitting element 10₂ and the third light emitting element 10₃ because the color filter layer is not provided in the second light emitting element 10₂ or the third light emitting element 10₃.

Specifically, when the first interface is formed with the first electrode 31 in the resonator structure, the first electrode 31 may be made of a material that reflects light with high efficiency as described above. When the light reflection layer 37 is provided below the first electrode 31 (on the first substrate side), the first electrode 31 may be made of a transparent conductive material as described above. When the light reflection layer 37 is provided on the base 26, and the first electrode 31 is provided on the interlayer insulating material layer 38 covering the light reflection layer 37, the first electrode 31, the light reflection layer 37, and the interlayer insulating material layer 38 may be made of the above-described materials. The light reflection layer 37 may be connected to the contact hole (contact plug) 27 (see FIG. 33) but does not have to be connected to the contact hole 27.

In some cases, instead of the filter layer TF, a green color filter layer or the like that transmits green light emitted from the second light emitting element 10₂ may be provided, or a blue color filter layer or the like that transmits blue light emitted from the third light emitting element 10₃ may be provided.

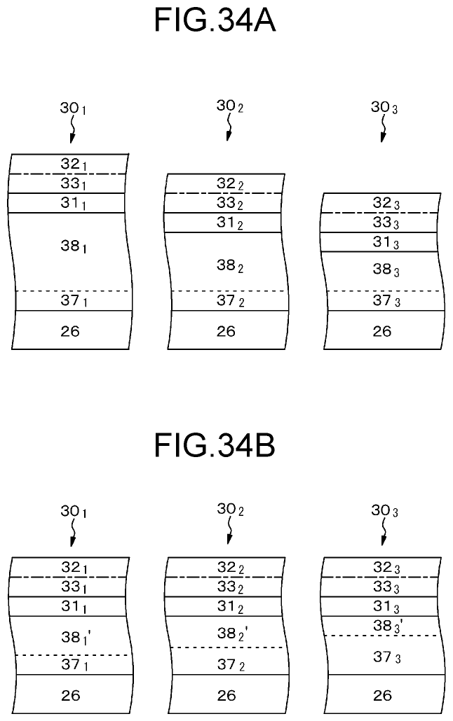

Hereinafter, the resonator structure will be described based on first to eighth examples with reference to FIGS. 34A (first example), 34B (second example), 35A (third example), 35B (fourth example), 36A (fifth example), 36B (sixth example), 37A (seventh example), and 37B and 37C (eighth example). In the first to fourth examples and the seventh example, the first electrode has the same thickness in the light emitting units, and the second electrode has the same thickness in the light emitting units. In the fifth to sixth examples, the first electrode has different thicknesses in the light emitting units, and the second electrode has the same thickness in the light emitting units. In the eighth example, the first electrode may have different thicknesses or may have the same thickness in the light emitting units, and the second electrode has the same thickness in the light emitting units.

In the following description, the light emitting units 30, 30′ constituting the first light emitting element 10₁, the second light emitting element 10₂, and the third light emitting element 10₃ are denoted by reference numerals 30₁, 30₂, 30₃, the first electrode is denoted by reference numerals 31₁, 31₂, 31₃, the second electrode is denoted by reference numerals 32₁, 32₂, 32₃, the organic layer is denoted by reference numerals 33₁, 33₂, 33₃, the light reflection layer is denoted by reference numerals 37₁, 37₂, 37₃, and the interlayer insulating material layer is denoted by reference numerals 38₁, 38₂, 38₃, 38₁′, 38₂′, 38₃′. In the following description, materials to be used are examples, and they may be changed as appropriate.

In the illustrated examples, the resonator lengths of the first light emitting element 10₁, the second light emitting element 10₂, and the third light emitting element 10₃ derived from Formulas (1-1) and (1-2) are shortened in the order of the first light emitting element 10₁, the second light emitting element 10₂, and the third light emitting element 10₃, that is, the value of SD₁₂ is shortened in the order of the first light emitting element 10₁, the second light emitting element 10₂, and the third light emitting element 10₃, but the resonator lengths are not limited to this configuration, and the optimum resonator length may be determined by appropriately setting the values of m₁ and m₂.

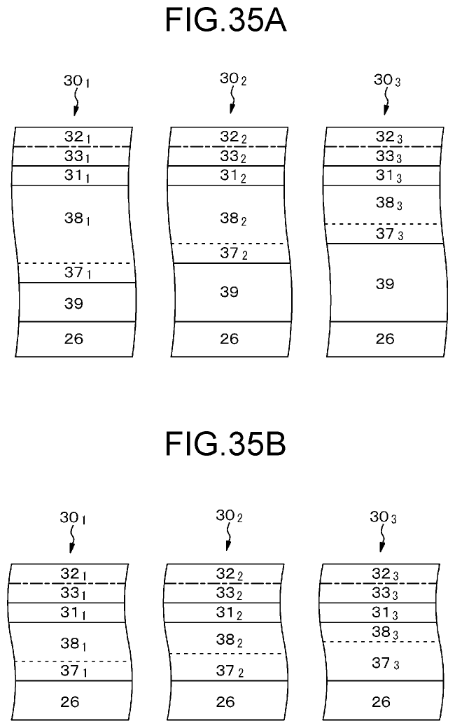

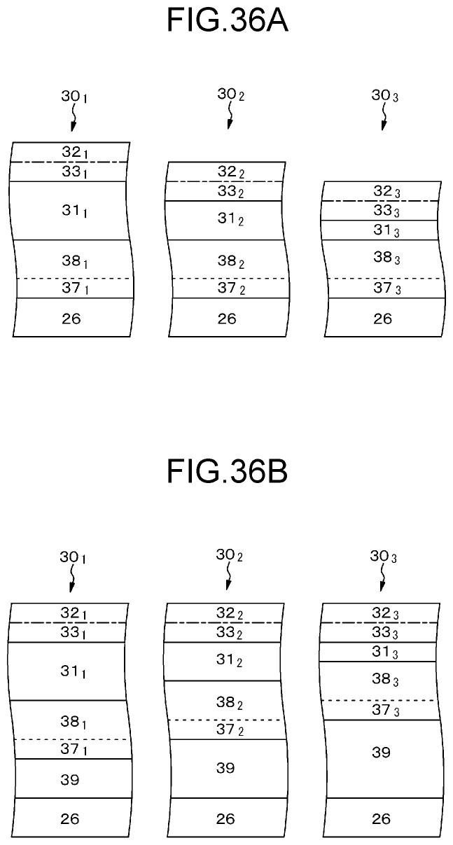

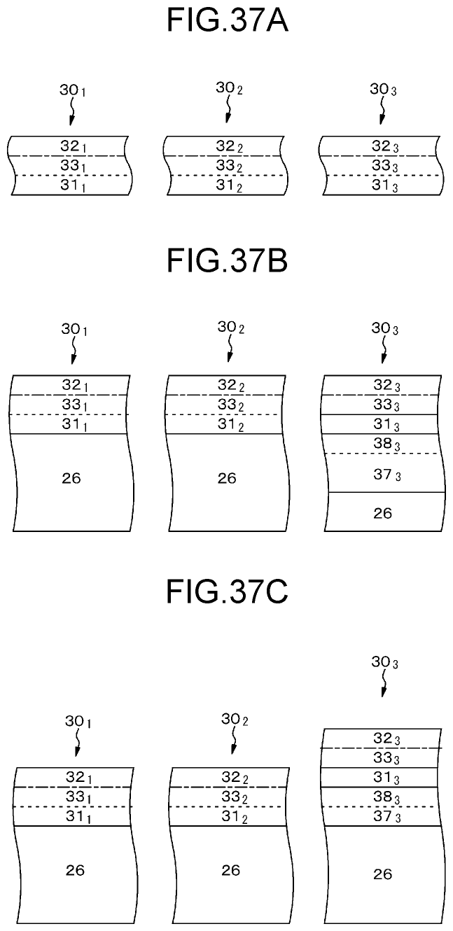

FIG. 34A is a conceptual diagram of light emitting elements having a resonator structure of the first example. FIG. 34B is a conceptual diagram of light emitting elements having a resonator structure of the second example. FIG. 35A is a conceptual diagram of light emitting elements having a resonator structure of the third example. FIG. 35B is a conceptual diagram of light emitting elements having a resonator structure of the fourth example. In some of the first to sixth examples and the eighth example, the interlayer insulating material layers 38, 38′ are formed beneath the first electrode 31 of the light emitting units 30, 30′ and the light reflection layer 37 is formed beneath the interlayer insulating material layers 38, 38′. In the first to fourth examples, the thicknesses of the interlayer insulating material layers 38, 38′ are different in the light emitting units 30₁, 30₂, 30₃. By appropriately setting the thicknesses of the interlayer insulating material layers 38₁, 38₂, 38₃, 38₁′, 38₂′, 38₃′, it is possible to set an optical distance at which optimum resonance is generated with respect to the emission wavelength of the light emitting units 30, 30′.

In the first example, the first interface (indicated by a dotted line in the drawings) is set to have the same level in the light emitting units 30₁, 30₂, 30₃, while the level of the second interface (indicated by one-dot chain line in the drawings) is different in the light emitting units 30₁, 30₂, 30₃. In the second example, the first interface is set to have different levels in the light emitting units 30₁, 30₂, 30₃, while the level of the second interface is the same in the light emitting units 30₁, 30₂, 30₃.

In the second example, the interlayer insulating material layers 38₁′, 38₂′, 38₃′ are formed of an oxide film in which the surface of the light reflection layer 37 is oxidized. The interlayer insulating material layer 38′ made of an oxide film is made of, for example, aluminum oxide, tantalum oxide, titanium oxide, magnesium oxide, zirconium oxide, or the like depending on the material constituting the light reflection layer 37. The surface of the light reflection layer 37 may be oxidized by, for example, the following method. That is, immerse the first substrate 41 on which the light reflection layer 37 is formed in an electrolytic solution filled in a container. Dispose a cathode to face the light reflection layer 37. Then, anodize the light reflection layer 37 using the light reflection layer 37 as an anode. The film thickness of the oxide film formed through the anodization is proportional to the potential difference between the light reflection layer 37 as an anode and the cathode. Thus, anodization is performed in a state where voltages corresponding to the light emitting units 30₁, 30₂, 30₃ are applied to the light reflection layers 37₁, 37₂, 37₃, respectively. As a result, the interlayer insulating material layers 38₁′, 38₂′, 38₃′ formed of an oxide film having different thicknesses can be collectively formed on the surface of the light reflection layer 37. The thicknesses of the light reflection layers 37₁, 37₂, 37₃ and the thicknesses of the interlayer insulating material layers 38₁′, 38₂′, 38₃′ are different in the light emitting units 30₁, 30₂, 30₃.

In the third example, an underlying film 39 is disposed beneath the light reflection layer 37, and the underlying film 39 has different thicknesses in the light emitting units 30₁, 30₂, 30₃. That is, in the illustrated example, the thickness of the underlying film 39 is increased in the order of the light emitting unit 30₁, the light emitting unit 30₂, and the light emitting unit 30₃.

In the fourth example, the thicknesses of the light reflection layers 37₁, 37₂, 37₃ at the time of film formation are different in the light emitting units 30₁, 30₂, 30₃. In the third and fourth examples, the second interface is set to have the same level in the light emitting units 30₁, 30₂, 30₃, while the level of the first interface is different in the light emitting units 30₁, 30₂, 30₃.

In the fifth and sixth examples, the thicknesses of the first electrodes 31₁, 31₂, 31₃ are different in the light emitting units 30₁, 30₂, 30₃. The light reflection layer 37 has the same thickness in the light emitting units 30.

In the fifth example, the level of the first interface is the same in the light emitting units 30₁, 30₂, 30₃, while the level of the second interface is different in the light emitting units 30₁, 30₂, 30₃.

In the sixth example, the underlying film 39 is disposed beneath the light reflection layer 37, and the underlying film 39 has different thicknesses in the light emitting units 30₁, 30₂, 30₃. That is, in the illustrated example, the thickness of the underlying film 39 is increased in the order of the light emitting unit 30₁, the light emitting unit 30₂, and the light emitting unit 30₃. In the sixth example, the second interface is set to have the same level in the light emitting units 30₁, 30₂, 30₃, while the level of the first interface is different in the light emitting units 30₁, 30₂, 30₃.

In the seventh example, the first electrodes 31₁, 31₂, 31₃ also serve as light reflection layers, and the optical constant (specifically, the phase shift amount) of the material constituting the first electrodes 31₁, 31₂, 31₃ is different in the light emitting units 30₁, 30₂, 30₃. For example, the first electrode 31₁ of the light emitting unit 30₁ may be made of copper (Cu), and the first electrode 31₂ of the light emitting unit 30₂ and the first electrode 31₃ of the light emitting unit 30₃ may be made of aluminum (Al).

In the eighth example, the first electrodes 31₁, 31₂ also serve as light reflection layers, and the optical constant (specifically, the phase shift amount) of the material constituting the first electrodes 31₁, 31₂ is different in the light emitting units 30₁, 30₂. For example, the first electrode 31₁ of the light emitting unit 30₁ may be made of copper (Cu), and the first electrode 31₂ of the light emitting unit 30₂ and the first electrode 31₃ of the light emitting unit 30₃ may be made of aluminum (Al). In the eighth example, for example, the seventh example is applied to the light emitting units 30₁, 30₂, and the first example is applied to the light emitting unit 30₃. The thicknesses of the first electrodes 31₁, 31₂, 31₃ may be different or the same.

The present disclosure may also have the following configurations.

### [A01]<<Display Device>>

A display device comprising:
a first substrate;
a second substrate facing the first substrate;
a plurality of light emitting elements provided in a display region sandwiched between the first substrate and the second substrate; and
a sealing part that is provided in a peripheral region sandwiched between the first substrate and the second substrate and surrounding the display region, the sealing part sealing between the first substrate and the second substrate, wherein
the sealing part includes main sealing parts and a sub sealing part positioned between the main sealing parts,
an alignment mark is provided between the sub sealing part and the first substrate,
each of the main sealing part has a stacked structure of a light shielding member layer and a sealing member layer from the first substrate side, and
the sub sealing part has a stacked structure of a base material layer formed of a non-light shielding member and the sealing member layer from the first substrate side.

### [A02]

The display device according to [A01], wherein an extending part of the sealing member layer constituting the sub sealing part is formed on the light shielding member layer.

### [A03]

The display device according to [A01] or [A02], wherein
each of the light emitting elements includes a first electrode, an organic layer, a second electrode, and an optical path control unit from the first substrate side, and
the base material layer is made of a material constituting the optical path control unit.

### [A04]

The display device according to [A03], wherein
each of the light emitting elements includes a color filter layer between the second electrode and the optical path control unit, and
the light shielding member layer is made of a material constituting the color filter layer.

### [A05]

The display device according to [A04], wherein
each of the light emitting elements includes a planarization layer between the second electrode and the color filter layer, and
the base material layer is made of a material constituting the planarization layer.

### REFERENCE SIGNS LIST

10, 10₁, 10₂, 10₃ LIGHT EMITTING ELEMENT
20 TRANSISTOR
21 GATE ELECTRODE
22 GATE INSULATING LAYER
23 CHANNEL FORMATION REGION
24 SOURCE/DRAIN REGION
25 ELEMENT ISOLATION REGION
26 BASE
26A SURFACE OF BASE
27 CONTACT PLUG
28 INSULATING LAYER
28′ OPENING
29 RECESS
29A SLOPE OF RECESS
30, 30′, 30₁, 30₂, 30₃ LIGHT EMITTING UNIT
31, 31₁, 31₂, 31₃ FIRST ELECTRODE
32, 32₁, 32₂, 32₃ SECOND ELECTRODE
33, 33₁, 33₂, 33₃ ORGANIC LAYER
34 PROTECTIVE LAYER
34A SECOND PROTECTIVE LAYER
34B THIRD PROTECTIVE LAYER
34′ PLANARIZATION LAYER
35 BONDING MEMBER
36 UNDERLAYER
37, 37₁, 37₂, 37₃ LIGHT REFLECTION LAYER
38, 38′, 38₁, 38₂, 38₃, 38₁′, 38₂′, 38₃′ INTERLAYER INSULATING MATERIAL LAYER
39 UNDERLAYING FILM
41 FIRST SUBSTRATE
42 SECOND SUBSTRATE
50 SEALING PART
51 MAIN SEALING PART (FIRST SEALING PART)
52 SUB SEALING PART (SECOND SEALING PART)
53 SEALING MEMBER LAYER
53a EXTENDING PART OF SEALING MEMBER LAYER
54, 58 BASE MATERIAL LAYER
56, 57, 59 LIGHT SHIELDING MEMBER LAYER
61 MASK LAYER
62, 63, 64 RESIST LAYER
65 OPENING
71, 72, 73 OPTICAL PATH CONTROL UNIT (LENS MEMBER)
71a LIGHT INCIDENT SURFACE OF OPTICAL PATH CONTROL UNIT
71b LIGHT EMISSION SURFACE OF OPTICAL PATH CONTROL UNIT
74 LIGHT EMISSION DIRECTION CONTROL MEMBER
74a LIGHT INCIDENT SURFACE OF LIGHT EMISSION DIRECTION CONTROL MEMBER
74b LIGHT EMISSION SURFACE OF LIGHT EMISSION DIRECTION CONTROL MEMBER
74A SIDE SURFACE OF LIGHT EMISSION DIRECTION CONTROL MEMBER
211 CAMERA BODY
212 PHOTOGRAPHING LENS UNIT (INTERCHANGEABLE LENS)
213 GRIP
214 MONITOR DEVICE
215 ELECTRONIC VIEW FINDER (EYEPIECE WINDOW)
300 HEAD MOUNTED DISPLAY
301 MAIN BODY
302 ARM
303 LENS BARREL
310 EYEGLASSES
CF, CF_{R}, CF_{G}, CF_{B} COLOR FILTER LAYER
TF TRANSPARENT FILTER LAYER
BM BLACK MATRIX LAYER

1. A display device comprising:
a first substrate;
a second substrate facing the first substrate;
a plurality of light emitting elements provided in a display region sandwiched between the first substrate and the second substrate; and
a sealing part that is provided in a peripheral region sandwiched between the first substrate and the second substrate and surrounding the display region, the sealing part sealing between the first substrate and the second substrate, wherein
the sealing part includes main sealing parts and a sub sealing part positioned between the main sealing parts,
an alignment mark is provided between the sub sealing part and the first substrate,
each of the main sealing part has a stacked structure of a light shielding member layer and a sealing member layer from the first substrate side, and
the sub sealing part has a stacked structure of a base material layer formed of a non-light shielding member and the sealing member layer from the first substrate side.

2. The display device according to claim 1, wherein an extending part of the sealing member layer constituting the sub sealing part is formed on the light shielding member layer.

3. The display device according to claim 1, wherein
each of the light emitting elements includes a first electrode, an organic layer, a second electrode, and an optical path control unit from the first substrate side, and
the base material layer is made of a material constituting the optical path control unit.

4. The display device according to claim 3, wherein
each of the light emitting elements includes a color filter layer between the second electrode and the optical path control unit, and
the light shielding member layer is made of a material constituting the color filter layer.

5. The display device according to claim 4, wherein
each of the light emitting elements includes a planarization layer between the second electrode and the color filter layer, and
the base material layer is made of a material constituting the planarization layer.
